(19) United States
(12) Patent Application Publication
(10) Pub. No.: US 2026/0090176 A1
(43) Pub. Date: Mar. 26, 2026

(54) DISPLAY DEVICE

(71) Applicant: Sharp Display Technology Corporation, Kameyama City (JP)

(72) Inventor: Junichi MORINAGA, Kameyama City (JP)

(21) Appl. No.: 19/307,436

(22) Filed: Aug. 22, 2025

(30) Foreign Application Priority Data
Sep. 26, 2024 (JP) 2024-167540

(51) Int. Cl. H10H 29/85

(52) U.S. Cl. CPC H10H 29/857

(57) ABSTRACT

A display device includes a scan line, a signal line, a control line, pixel electrodes, a first switching component, and a second switching component. The first switching component includes a first electrode connected to one of the scan line and the control line, a second electrode connected to the signal line, a third electrode, and a first semiconductor section. The second switching component includes a fourth electrode connected to another one of the scan line and the control line, a fifth electrode connected to the third electrode, a sixth electrode, and a second semiconductor section. The pixel electrodes include a first pixel electrode that includes a first body portion and a first connection line portion that is connected to the first body portion and the sixth electrode. The first connection line portion crosses the control line or the signal line.

### CROSS REFERENCE TO RELATED APPLICATION

This application claims priority from Japanese Patent Application No. 2024-167540 filed on Sep. 26, 2024. The entire contents of the priority application are incorporated herein by reference.

### TECHNICAL FIELD

The present technology described herein relates to a display device with which variation of pixel electrode arrangement is increased.

### BACKGROUND

A liquid crystal display device has been known as one example of display devices. One example of such a liquid crystal display device includes scan lines and signal lines that are disposed in a matrix, control lines arranged parallel to the signal lines, first switching components, and second switching components. The first switching components are configured to be turned on in response to the driving signals supplied to the scan lines and apply the signals supplied to the signal lines to liquid crystals. The second switching components are connected in serial to the first switching components and configured to be controlled to be on and off by the signals supplied to the control lines.

With such a liquid crystal display device, the number of signal lines can be reduced such that the intervals between the terminals of the data driver are not reduced and therefore, power consumption and a cost can be reduced. However, in such a liquid crystal display device, every time period while image signals are supplied to the pixels of each row, the polarity of the image signals to be supplied to the signal lines are inverted. As a result, delay of the image signals to be supplied to the signal lines is likely to be increased and power consumption also increases. With the polarity of the image signals supplied to the signal lines being inverted for every frame to reduce power consumption, every two columns of the pixels having a same polarity may be arranged alternately. In such a configuration, display errors of stripes are likely to be seen because the arrangement of the pixel electrodes that are connected to the second switching components is fixed.

### SUMMARY

The technology described herein was made in view of the above circumstances. An object is to increase variation of pixel electrode arrangement.

(1) A display device according to the technology described herein includes a scan line extending along a first direction, a signal line extending along a second direction that crosses the first direction and crossing the scan line, a control line extending along the second direction and disposed to be spaced from the signal line and crossing the scan signal, pixel electrodes arranged in a matrix in the first direction and the second direction, a first switching component, and a second switching component. The first switching component includes a first electrode connected to one of the scan line and the control line, a second electrode connected to the signal line, a third electrode, and a first semiconductor section connected to the second electrode and the third electrode and overlapping the first electrode. The second switching component includes a fourth electrode connected to another one of the scan line and the control line, a fifth electrode connected to the third electrode, a sixth electrode connected to one of the pixel electrodes, and a second semiconductor section connected to the fifth electrode and the sixth electrode and overlapping the fourth electrode. The pixel electrodes include a first pixel electrode and the first pixel electrode includes a first body portion and a first connection line portion that is connected to the first body portion and the sixth electrode. The first connection line portion crosses the control line or the signal line.

(2) In the display device, in addition to (1), the control line or the signal line may be disposed between the first body portion and the second switching component that is connected to the first connection line portion.

(3) In the display device, in addition to (1) or (2), the first electrode may be connected to the scan line, and the fourth electrode may be connected to the control line.

(4) In the display device, in addition to (3), the second switching component may be disposed closer to the control line than the signal line.

(5) In the display device, in addition to (3) or (4), the first switching component may be disposed closer to the signal line than the control line.

(6) In the display device, in addition to any one of (3) to (5), the control line may include control lines that are arranged at intervals in the first direction. The control lines may include a first control line and a second control line. The signal line may include signal lines that are arranged at intervals in the first direction. The signal lines may include a first signal line. The second switching component may include second switching components that are arranged at intervals in the first direction. One of the second switching components that includes the fourth electrode connected to the first control line may be defined as a first control switching component. Another one of the second switching components that includes the fourth electrode connected to the second control line may be defined as a second control switching component. The first switching component may include first switching components that are arranged at intervals in the first direction. One of the first switching components that includes the second electrode connected to the first signal line and the third electrode connected to the fifth electrode of the first control switching component may be defined as a first signal switching component. Another one of the first switching components that includes the second electrode connected to the first signal line and the third electrode connected to the fifth electrode of the second control switching component may be defined as a second signal switching component.

(7) The display device may further include, in addition to (6), a first signal supply section connected to the control lines and configured to supply signals to the control lines and configured to supply high-level potential to the first control line and the second control line at different timings.

(8) In the display device, in addition to (6) or (7), the control lines may include a third control line and a fourth control line. The signal lines may include a second signal line. Other one of the second switching components that includes the fourth electrode connected to the third control line may be defined as a third control switching component. Other one of the second switching components that includes the fourth electrode connected to the fourth control line may be defined as a fourth control switching component. Other one of the first switching components that includes the second electrode connected to the second signal line and the third electrode connected to the fifth electrode of the third control switching component may be defined as a third signal switching component. Other one of the first switching components that includes the second electrode connected to the second signal line and the third electrode connected to the fifth electrode of the fourth control switching component may be defined as a fourth signal switching component.

(9) The display device may further include, in addition to (8), a first short circuit line extending along the first direction and connected to the first signal line and the second signal line to cause a short circuit between the first signal line and the second signal line, a first extending line connected to one of the first signal line, the second signal line, and the first short circuit line, and a second supply section connected to the first extending line and configured to supply signals to the first extending line.

(10) The display device may further include, in addition to (9), a first signal supply section connected to the control lines and configured to supply signals to the control lines. The first signal supply section may be configured to supply high-level potential to the first control line, the second control line, the third control line, and the fourth control line at different timings. The second signal supply section may be configured to supply a signal to the first signal switching component in synchronization with a timing when high-level potential is supplied to the first control line, supply a signal to the second signal switching component in synchronization with a timing when high-level potential is supplied to the second control line, supply a signal to the third signal switching component in synchronization with a timing when high-level potential is supplied to the third control line, and supply a signal to the fourth signal switching component in synchronization with a timing when high-level potential is supplied to the fourth control line.

(11) In the display device, in addition to any one of (8) to (10), the first signal line may be between the first control line and the second control line in the first direction. The second signal line may be between the third control line and the fourth control line in the first direction. The signal lines may include a third signal line that is between the second control line and the third control line in the first direction. Other one of the first switching components that includes the second electrode connected to the third signal line may be defined as a fifth signal switching component. Other one of the first switching components that includes the second electrode connected to the third signal line and sandwiches the third signal line with the fifth signal switching component may be defined as a sixth signal switching component. Other one of the second switching components that includes the fifth electrode connected to the third electrode of the fifth signal switching component may be defined as a fifth control switching component. Other one of the second switching components that includes the fifth electrode connected to the third electrode of the sixth signal switching component may be defined as a sixth control switching component. The fourth electrode of the fifth control switching component may be connected to the second control line and the fourth electrode of the sixth control switching component may be connected to the third control line.

(12) In the display device, in addition to (11), the signal lines may include a fourth signal line that sandwiches the fourth control line with the second signal line. Other one of the first switching components that includes the second electrode connected to the fourth signal line may be defined as a seventh signal switching component. Other one of the second switching components that includes the fifth electrode connected to the third electrode of the seventh signal switching component may be defined as a seventh control switching component. The fourth electrode of the seventh control switching component may be connected to the fourth control line.

(13) In the display device, in addition to (11) or (12, the first pixel electrode may include first pixel electrodes and the pixel electrodes may further include second pixel electrodes. Each of the second pixel electrodes may include a second body portion and a second connection line portion that is connected to the second body portion and the sixth electrode and does not cross the control line and the signal line. One of the first pixel electrodes may include the first body portion that is on an opposite side from the first signal line with respect to the first control line in the first direction and the first connection line portion that is connected to the sixth electrode of the first control switching component and crosses the first control line. Other one of the first pixel electrodes may include the first body portion that is between the third signal line and the third control line in the first direction and the first connection line portion that is connected to the sixth electrode of the third control switching component and crosses the third control line. Other one of the first pixel electrodes may include the first body portion that is between the third control line and the second signal line in the first direction and the first connection line portion that is connected to the sixth electrode of the sixth control switching component and crosses the third control line. One of the second pixel electrodes may include the second body portion that is between the first signal line and the second control line in the first direction and the second connection line portion that is connected to the sixth electrode of the second control switching component. Other one of the second pixel electrodes may include the second body portion that is between the second signal line and the fourth control line in the first direction and the second connection line portion that is connected to the sixth electrode of the fourth control switching component. Other one of the second pixel electrodes may include the second body portion that is between the second control line and the third signal line in the first direction and the second connection line portion that is connected to the sixth electrode of the fifth control switching component.

(14) In the display device, in addition to (13), the first body portion and the second body portion may have a same area and the first connection line portion and the second connection line portion may have a same area.

(15) In the display device, in addition to (13) or (14), the first connection line portion may have a first length extending from the first body portion to the sixth electrode and the second connection line portion may have a second length extending from the second body portion to the sixth electrode, and the first length may be same as the second length.

(16) In the display device, in addition to (11) or (15), the first pixel electrode may include first pixel electrodes. One of the first pixel electrodes may include the first body portion that is between the first signal line and the second control line in the first direction and the first connection line portion that is connected to the sixth electrode of the first control switching component and crosses the first signal line. Other one of the first pixel electrodes may include the first body portion that is between the second control line and the third signal line in the first direction and the first connection line portion that is connected to the sixth electrode of the second control switching component and crosses the second control line. Other one of the first pixel electrodes may include the first body portion that is between the third signal line and the third control line in the first direction and the first connection line portion that is connected to the sixth electrode of the fifth control switching component and crosses the third signal line. Other one of the first pixel electrodes may include the first body portion that is between the third control line and the second signal line in the first direction and the first connection line portion that is connected to the sixth electrode of the sixth control switching component and crosses the third control line. Other one of the first pixel electrodes may include the first body portion that is between the second signal line and the fourth control line in the first direction and the first connection line portion that is connected to the sixth electrode of the third control switching component and crosses the second signal line. Other one of the first pixel electrodes may include the first body portion that is on an opposite side from the second signal line with respect to the fourth control line in the first direction and the first connection line portion that is connected to the sixth electrode of the fourth control switching component and crosses the fourth control line.

(17) The display device may further include, in addition to (13) or (16), a second signal supply section connected to the signal lines and configured to supply signals to the signal lines. Signals supplied by the second signal supply section to the first signal line and the second signal line and signals supplied by the second signal supply section to the third signal line may have opposite polarities.

(18) The display device may further include, in addition to (17), a first signal supply section connected to the control lines and configured to supply signals to the control lines. The second signal supply section may be configured to supply signals having a same polarity to the first signal line, the second signal line, and the third signal line in synchronization with supply of high-level potential to the first control line, the second control line, the third control line, and the fourth control line from the first signal supply section.

(19) In the display device, in addition to (1) or (2), the first electrode may be connected to the control line, and the fourth electrode may be connected to the scan line.

According to the technology described herein, variation of pixel electrode arrangement is increased.

### BRIEF DESCRIPTION OF THE DRAWINGS

FIG. 1 is a plan view illustrating a liquid crystal panel, drivers, a flexible substrate, and a control board according to a first embodiment.

FIG. 2 is a cross-sectional view illustrating the liquid crystal panel, the driver, and the flexible substrate according to the first embodiment.

FIG. 3 is a plan view illustrating pixel arrangement of an array substrate of the liquid crystal panel according to the first embodiment.

FIG. 4 is a cross-sectional view illustrating a portion of the liquid crystal panel according to the first embodiment along iv-iv line in FIG. 3.

FIG. 5 is a cross-sectional view illustrating a portion of the liquid crystal panel according to the first embodiment along v-v line in FIG. 3.

FIG. 6 is a cross-sectional view illustrating a portion of the liquid crystal panel according to the first embodiment along vi-vi line in FIG. 3.

FIG. 7 is a plan view illustrating a first area A1 in FIG. 3.

FIG. 8 is a plan view illustrating a second area A2 in FIG. 3.

FIG. 9 is a plan view illustrating a third area A3 in FIG. 3.

FIG. 10 is a circuit diagram illustrating an electrical configuration of the liquid crystal panel according to the first embodiment.

FIG. 11 is a timing chart related to operations of a first TFT and a second TFT according to the first embodiment.

FIG. 12 is a plan view typically illustrating pixel arrangement in the array substrate according to the first embodiment and polarities of the pixel electrodes that are charged based on the timing chart in FIG. 11.

FIG. 13 is a timing chart related to operations of the first TFT and the second TFT according to the first embodiment after one frame display period of FIG. 11.

FIG. 14 is a plan view typically illustrating pixel arrangement in the array substrate according to the first embodiment and polarities of the pixel electrodes that are charged based on the timing chart in FIG. 13.

FIG. 15 is a plan view illustrating pixel arrangement of an array substrate of a liquid crystal panel according to a second embodiment.

FIG. 16 is a plan view illustrating the pixel arrangement of a first pixel column to a fourth pixel column.

FIG. 17 is a plan view illustrating the pixel arrangement of a third pixel column to a sixth pixel column.

FIG. 18 is a plan view illustrating the pixel arrangement of a fifth pixel column to an eighth pixel column.

FIG. 19 is a circuit diagram illustrating an electrical configuration of the liquid crystal panel according to the second embodiment.

FIG. 20 is a timing chart related to operations of a first TFT and a second TFT according to the second embodiment.

FIG. 21 is a plan view typically illustrating pixel arrangement in the array substrate according to the second embodiment and polarities of the pixel electrodes that are charged based on the timing chart in FIG. 20.

FIG. 22 is a timing chart related to operations of the first TFT and the second TFT according to the second embodiment after one frame display period of FIG. 20.

FIG. 23 is a plan view typically illustrating pixel arrangement in the array substrate according to the second embodiment and polarities of the pixel electrodes that are charged based on the timing chart in FIG. 22.

FIG. 24 is a plan view illustrating pixel arrangement in an array substrate of a liquid crystal panel according to a third embodiment.

FIG. 25 is a circuit diagram illustrating an electrical configuration of a liquid crystal panel according to the third embodiment.

### DETAILED DESCRIPTION

### First Embodiment

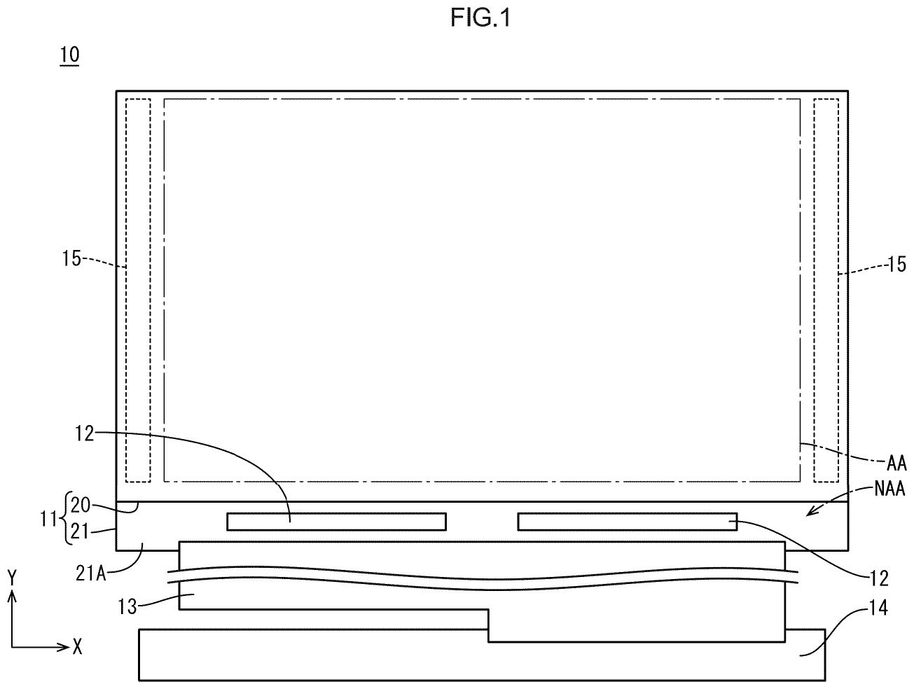

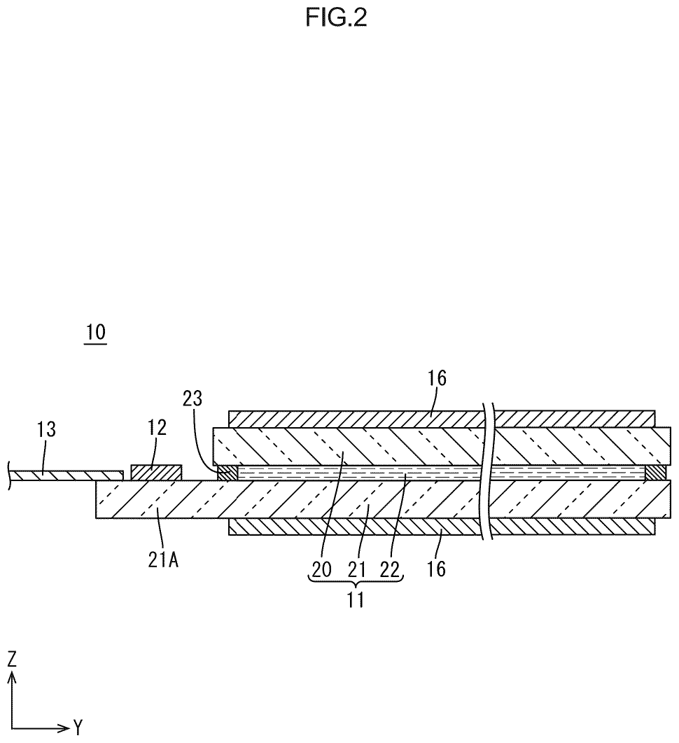

A first embodiment will be described with reference to FIGS. 1 to 14. In this embodiment section, a liquid crystal display device 10 (a display device) will be described. X-axes, Y-axes, and Z-axes may be present in the drawings. The axes in each drawing correspond to the respective axes in other drawings. An upper side and a lower side in FIGS. 2, 4, 5, and 6 correspond to a front side and a back side of the liquid crystal display device 10, respectively.

As illustrated in FIG. 1, the liquid crystal display device 10 at least includes a liquid crystal panel 11 (a display panel) that has a laterally long rectangular plan view shape and displays an image and a backlight unit (a lighting device) that supplies light to the liquid crystal panel 11 for displaying. The backlight unit is disposed behind (on a back surface side of) the liquid crystal panel 11. The backlight unit includes light sources configured to emit white light (e.g., LEDs) and optical members for converting the light from the light sources into planar light by applying optical effects to the light from the light sources. A middle section of a plate surface of the liquid crystal panel 11 is configured as a display area AA in which images are displayed. An outer section in a frame shape surrounding the display area AA on the plate surface of the liquid crystal panel 11 is configured as a non-display area NAA in which the images are not displayed.

The liquid crystal panel 11 will be described in detail with reference to FIGS. 1 and 2. As illustrated in FIGS. 1 and 2, the liquid crystal panel 11 includes a pair of substrates 20, 21 that are bonded to each other. One of the substrates 20, 21 on the front side is an opposed substrate 20 and another one on the back side is an array substrate 21. The opposed substrate 20 and the array substrate 21 include glass substrates and various kinds of films that are formed in layers on an inner surface side of the glass substrates. A liquid crystal layer 22 is disposed between the substrates 20 and 21. The liquid crystal layer 22 includes liquid crystal molecules having optical characteristics that vary according to application of electric field. A sealing portion 23 is disposed between the outer peripheral portions of the substrates 20, 21 for sealing the liquid crystal layer 22. The sealing portion 23 is formed in a frame shape and surrounds the liquid crystal layer 22. Polarizing plates 16 are attached to outer surfaces of the substrates 20 and 21.

As illustrated in FIGS. 1 and 2, the opposed substrate 20 has a short-side dimension that is smaller than a short-side dimension of the array substrate 21. The opposed substrate 20 is bonded to the array substrate 21 such that one of the long sides of the opposed substrate 20 is aligned with a corresponding one of the long sides of the array substrate 21. Therefore, a long side edge section including another one of the long sides of the array substrate 21 projects from another one of the long sides of the opposed substrate 20 and a projecting long side edge section is an uncovered section 21A. An entire area of the uncovered section 21A is the non-display area NAA and drivers 12 (a second signal supply section) that are components for supplying various signals and a flexible substrate 13 are mounted on the uncovered section 21A.

As illustrated in FIGS. 1 and 2, the drivers 12 are mounted on the uncovered section 21A of the array substrate 21 through the chip-on-glass (COG) technology. The drivers 12 are LSI chips including driver circuits therein. The driver 12 processes the various kinds of signals transmitted from the flexible substrate 13 and supplies image signals to source lines 28, for instance. The drivers 12 are disposed on the uncovered section 21A and on one side with respect to the Y-axis direction and arranged adjacent to each other. The drivers 12 are disposed between the flexible substrate 13 and the display area AA. Two drivers 12 are disposed on the uncovered section 21A to be spaced from each other with respect to the X-axis direction. The driver 12 has a laterally elongated rectangular plan view shape. The long side dimension of the driver 12 is shorter than the long side dimension of the display area AA.

The flexible substrate 13 includes a substrate made of synthetic resin (e.g., polyimide-based resin) having insulating property and flexibility and multiple traces formed on the substrate. As illustrated in FIGS. 1 and 2, a first end of the flexible substrate 13 is connected to the uncovered section 21A of the array substrate 21 and a second end of the flexible substrate 13 is connected to a control board 14 (a first signal supply section). The flexible substrate 13 is connected to an end of the uncovered section 21A that is an opposite end from the display area AA with respect to the drivers 12 in the Y-axis direction. Namely, the flexible substrate 13 is on a portion of the uncovered section 21A such that the drivers 12 are between the display area AA and the flexible substrate 13. The control board 14 includes a rigid substrate made of synthetic resin (such as paper phenol and glass epoxy resin) and circuit components that are mounted on the substrate. The circuit components include a power IC (integrated circuit), a timing controller that generates various kinds of signals to be supplied to the drivers 12, and a level shifter IC for controlling (decreasing and increasing) a voltage level. The control board 14 includes a connector portion that is connected to the flexible substrate 13. The flexible substrate 13 is folded such that the control board 14 is disposed behind the backlight unit. The control board 14 is disposed to overlap the backlight unit. The control board 14 is configured to supply various kinds of signals to the drivers 12 and supply control signals (switching signals) to control lines 29. The potential of the control signals is periodically changed to be higher than a threshold voltage of a second TFT 25.

As illustrated in FIG. 1, gate driver circuits 15 (a third signal supply section) are disposed in the non-display area NAA of the array substrate 21. A pair of gate driver circuits 15 are disposed to sandwich the display area AA with respect to the X-axis direction. The gate driver circuit 15 is disposed in a belt shape area of the array substrate 21 extending in the short-side direction (the Y-axis direction). The gate driver circuits 15 are for supplying scan signals to gate lines 27 and are monolithically fabricated on the array substrate 21. The scan signals have potential higher than a threshold voltage of a first TFT 24.

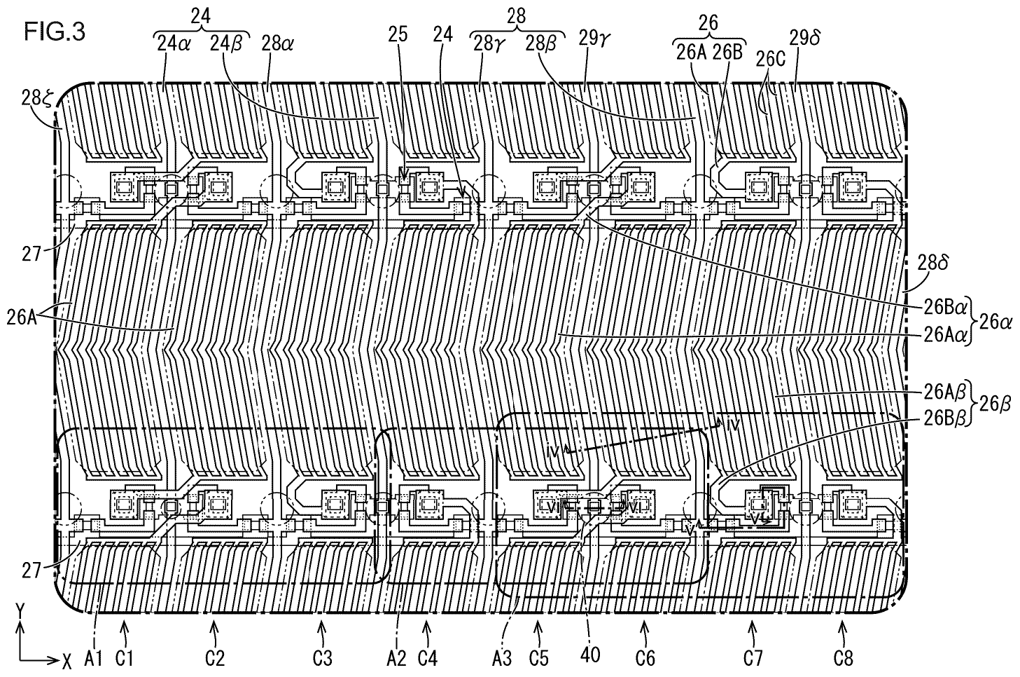

As illustrated in FIG. 3, first TFTs 24 (first switching components), second TFTs 25 (second switching components), and pixel electrode 26 are arranged in rows and columns (a matrix). The first TFTs 24, the second TFTs 25, and the pixel electrodes 26 that are arranged along the X-axis direction are configured as a pixel row and the pixel rows are arranged in the Y-axis direction. The first TFTs 24, the second TFTs 25, and the pixel electrodes 26 that are arranged along the Y-axis direction are configured as a pixel column and the pixel columns are arranged in the X-axis direction. Gate lines 27 (scan lines), source lines 28 (signal lines, image lines, data lines), and the control lines 29 are routed perpendicular to each other to surround the first TFTs 24, the second TFTs 25, and the pixel electrodes 26.

As illustrated in FIG. 3, the gate line 27 extends substantially straight along the X-axis direction (a first direction) to laterally cross the display area AA and is connected to the first TFTs 24 included in one pixel row. The gate lines 27 are arranged at intervals with respect to the Y-axis direction (a second direction). The number of gate lines 27 is same as the number of pixel electrodes 26 arranged in the Y-axis direction.

As illustrated in FIG. 3, the source lines 28 extend substantially along the Y-axis direction to vertically cross the display area AA. The source line 28 is connected to the first TFTs 24 included in two pixel columns that are adjacent to each other and sandwich the source line 28. The source line 28 is bent several times and includes an inclined portion that is inclined slightly with respect to the Y-axis direction and a straight portion that extends along the Y-axis direction. The source lines 28 are arranged at intervals with respect to the X-axis direction.

As illustrated in FIG. 3, the control lines 29 extend substantially along the Y-axis direction to vertically cross the display area AA similar to the source lines 28. The control line 29 is connected to the second TFTs 25 included in two pixel columns that are adjacent to each other and sandwich the control line 29. The control lines 29 are arranged at intervals with respect to the X-axis direction. Similar to the source line 28, the control line 29 is bent several times and includes an inclined portion that is inclined slightly with respect to the Y-axis direction and a straight portion that extends along the Y-axis direction. The source lines 28 and the control lines 29 are alternately arranged at substantially equal intervals with respect to the X-axis direction. The number of source lines 28 is substantially same as the number of control lines 29 and the total of the source lines 28 and the control lines 29 is same as the number of pixel electrodes 26 arranged in the X-axis direction.

As illustrated in FIG. 3, the first TFT 24 and the second TFT 25 are sandwiched between the source line 28 and the control line 29 with respect to the X-axis direction and are sandwiched between the gate line 27 and the pixel electrode 26 (specifically, a body portion 26A) with respect to the Y-axis direction. The first TFT 24 is connected to the gate line 27, the source line 28, and the second TFT 25. The first TFTs 24 are driven based on a scan signal supplied to the gate line 27 and accordingly, image signals suppled to the source lines 28 are supplied to the second TFTs 25. Therefore, in this embodiment, the first TFTs 24 are signal TFTs (signal switching component) that receive image signals from the source lines 28.

As illustrated in FIG. 3, the second TFT 25 is connected to the pixel electrode 26, the control line 29, and the first TFT 24. The second TFTs 25 are driven based on control signals supplied to the control lines 29 and accordingly, image signals suppled from the first TFTs 24 are supplied to the pixel electrodes 26. Therefore, in this embodiment, the second TFTs 25 are control TFTs (control switching component) that are configured to control supply of image signals to the pixel electrodes 26. By controlling driving of the first TFT 24 and the second TFT 25 at an appropriate timing, the pixel electrode 26 can be charged to have potential that is related to the image signal supplied to the source line 28.

As illustrated in FIG. 3, the pixel electrode 26 includes the body portion 26A having a vertically long shape and a connection line portion 26B that is connected to the body portion 26A and the second TFT 25. The body portion 26A is sandwiched between the gate line 27 and each of the first TFT 24 and the second TFT 25 in the Y-axis direction and sandwiched between the source line 28 and the control line 29 in the X-axis direction. The body portions 26A are arranged along the X-axis direction so as to have the source line 28 or the control line 29 therebetween. The body portions 26A that are arranged along the X-axis direction are configured as the pixel row. The first TFTs 24 and the second TFTs 25 that are included in one pixel row are sandwiched between the body portions 26A, which are included in the one pixel row, and the gate line 27 in the Y-axis direction. The body portions 26A are arranged along the Y-axis direction so as to sandwich at least portions of the first TFT 24, the second TFT 25, and the gate line 27. The body portions 26A that are arranged along the Y-axis direction are configured as the pixel column. The first TFTs 24 and the second TFTs 25 that are included in one pixel column are sandwiched between the body portions 26A, which are included in the one pixel column, and the gate line 27 in the Y-axis direction. The body portions 26A are bent at middle sections in the longitudinal direction so as to extend along the source line 28 and the control line 29. Specifically, the body portion 26A is angled at a middle and formed in a shallow V-shape having an obtuse vertex angle and end portions are slightly inclined with respect to the Y-axis direction. The end portions of the body portion 26A extend along the inclined portions of the source line 28 and the control line 29. The body portions 26A include bent portions at middle sections. The body portion 26A includes slits 26C (five slits 26C in FIG. 3) extending along a longitudinal direction of the body portion 26A. The number, the shape, and the area of the slit 26C may be altered as appropriate other than those illustrated in the drawings.

As illustrated in FIG. 3, the connection line portion 26B extends from the body portion 26A to the second TFT 25 (a drain line section 43), which is a target to be connected. The connection line portion 26B includes a wide section that is wider than other section and is connected to the second TFT 25. A detailed configuration of the connection line portion 26B will be described later.

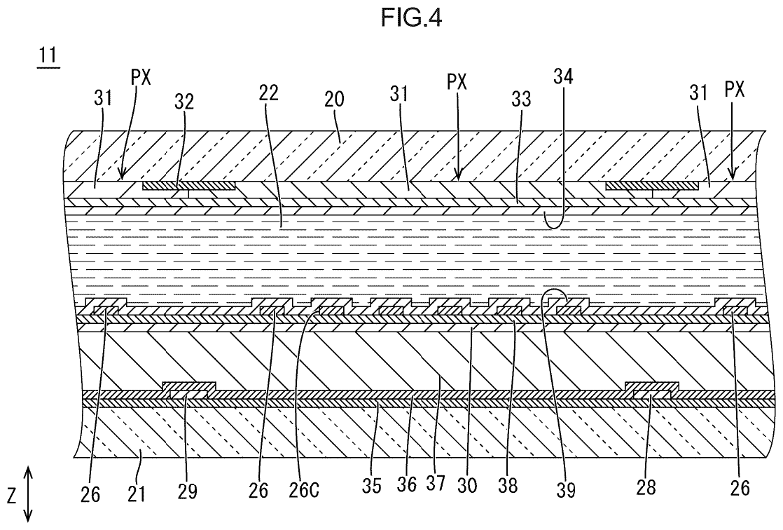

A cross-sectional configuration of the pixel electrodes 26 in a middle section of the liquid crystal panel 11 with respect to the Y-axis direction will be described with reference to FIG. 4. FIG. 4 is a typical cross-sectional view along line iv-iv in FIG. 3. As illustrated in FIG. 4, a common electrode 30 is formed on an inner surface side of the array substrate 21 in the display area AA to overlap all the pixel electrodes 26. The common electrode 30 is disposed on a lower layer side of the pixel electrodes 26. The common electrode 30 is supplied with a common potential signal (a reference potential signal) of a common potential (a reference potential) from the control board 14 via the flexible substrate 13. The common electrode 30 spreads over a substantially entire area of the display area AA. With the pixel electrode 26 being charged, a potential difference occurs between the pixel electrode 26 and the common electrode 30 that are overlapped. Then, a fringe electric field (an oblique electric field) is created between an opening edge of the slit 26C of the pixel electrode 26 and the common electrode 30. The fringe electric field includes a component parallel to the plate surface of the array substrate 21 and a component normal to the plate surface of the array substrate 21. With the fringe electric field, orientations of the liquid crystal molecules included in the liquid crystal layer 22 can be controlled. Namely, the liquid crystal panel 11 according to this embodiment operates in the fringe field switching (FFS) mode.

As illustrated in FIG. 4, color filters 31 are disposed in the display area AA of the opposed substrate 20 of the liquid crystal panel 11 so as to overlap the pixel electrodes 26 of the array substrate 21, respectively. The color filters 31 that exhibit three different colors of red (R), green (G), and blue (B) are arranged alternately and repeatedly along the X-axis direction. The color filters 31 exhibiting three different colors extend along the Y-axis direction (the second direction) and are arranged in stripes as a whole. More specifically, the color filters 31 exhibiting three different colors extend substantially along the Y-axis direction and parallel to the inclined portions of the source line 28 and the control line 29 and are bent in a zigzag form similar to the source lines 28 and the control lines 29. The color filters 31 are arranged opposite the body portions 26A of the pixel electrodes 26 of the array substrate 21, respectively. The color filter 31 and the corresponding pixel electrode 26 are configured as a pixel PX, which is a display unit.

As illustrated in FIG. 4, a light blocking portion 32 (a black matrix) that defines (boundaries) the color filters 31 (the pixel electrodes 26) that are adjacent to each other with respect to the X-axis direction and the Y-axis direction is disposed in the display area AA of the opposed substrate 20. The light blocking portion 32 is disposed in the non-display area NAA in addition to the display area AA. The light blocking portion 32 is formed in a grid pattern in the display area AA to overlap the TFTs 24, 25, the gate lines 27, the source lines 28, and the control lines 29 and is formed in a solid manner in the non-display area NAA. On an upper layer side of the color filters 31 and the light blocking portion 32, an overcoat film 33 is disposed as illustrated in FIG. 4. The overcoat film 33 is disposed in a solid manner on a substantially entire area of the opposed substrate 20. The overcoat film 33 is made of organic material such as acrylic resin (PMMA, for instance) and is for planarizing steps that are formed on a lower layer side. A first alignment film 34 for orienting the liquid crystal molecules in the liquid crystal layer 22 is formed on an upper layer side of the overcoat film 33 (on an innermost surface of the opposed substrate 20). The first alignment film 34 is made of polyimide, for instance.

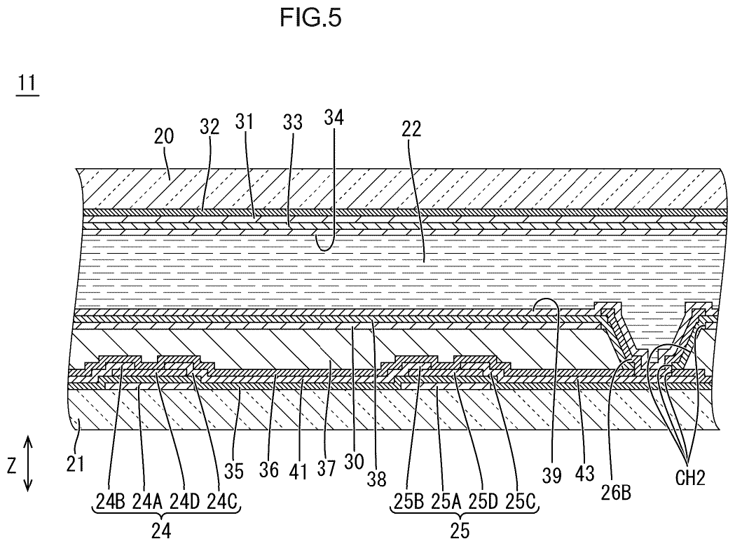

Films disposed on top of each other on the inner surface side of the array substrate 21 will be described with reference to FIG. 5. FIG. 5 illustrates a cross-sectional typical configuration along v-v line in FIG. 3. As illustrated in FIG. 5, on the array substrate 21, a first metal film, a gate insulating film 35, a semiconductor film, a second metal film, a first interlayer insulating film 36, a planarization film 37, a first transparent electrode film, a second interlayer insulating film 38, a second transparent electrode film, and a second alignment film 39 are disposed on top of each other in this sequence from a lower layer side. The first metal film and the second metal film may be a single-layer film made of one kind of metal, a multilayer film made of a material containing different kinds of metals, or an alloy. Examples of the metals include copper, titanium, aluminum, molybdenum, and tungsten. With such a configuration, the first metal film and the second metal film have electrically conductive properties and light blocking properties. Portions of the first metal film are configured as the gate lines 27. Portions of the second metal film are configured as the source lines 28 and the control lines 29. The semiconductor film is a thin film made of material such as oxide semiconductor and amorphous silicon and portions of the semiconductor film are configured as portions of the TFTs 24, 25. The first transparent electrode film and the second transparent electrode film are made of a transparent electrode material (e.g., indium tin oxide (ITO) and indium zinc oxide (IZO)). A portion of the first transparent electrode film is configured as the common electrode 30. Portions of the second transparent electrode film are configured as the pixel electrodes 26. The second alignment film 39 is made of polyimide, for instance, similar to the first alignment film 34, and is for orienting the liquid crystal molecules in the liquid crystal layer 22.

The gate insulating film 35, the first interlayer insulating film 36, and the second interlayer insulating film 38 are made of an inorganic material such as silicon nitride (SiN_{X}) and silicon oxide (SiO₂). The planarization film 37 is made of an organic material such as PMMA (acrylic resin). The planarization film 37 has a thickness of from about 1 μm to 3 μm and is much thicker than the gate insulating film 35, the first interlayer insulating film 36, and the second interlayer insulating film 38. The planarization film 37 planarizes the inner surface (a surface opposite the liquid crystal layer 22) of the array substrate 21. The gate insulating film 35 insulates the first metal film in the lower layer from the semiconductor film and the second metal film in the upper layer. For instance, in crossing portions of the gate lines 27, which are portions of the first metal film, and the source lines 28, which are portions of the second metal film, are insulated from each other by the gate insulating film 35. The first interlayer insulating film 36 and the planarization film 37 insulate semiconductor film and the second metal film in the lower layer from the first transparent electrode film in the upper layer. For instance, the source lines 28, which are portions of the second metal film, and the common electrode 30, which is a portion of the first transparent electrode film, are insulated from each other by the first interlayer insulating film 36 and the planarization film 37. The second interlayer insulating film 38 insulates the first transparent electrode film in the lower layer from the second transparent electrode film in the upper layer. For instance, the common electrode 30, which is a portion of the first transparent electrode film, and the pixel electrodes 26, which are portions of the second transparent electrode film, are insulated from each other by the second interlayer insulating film 38.

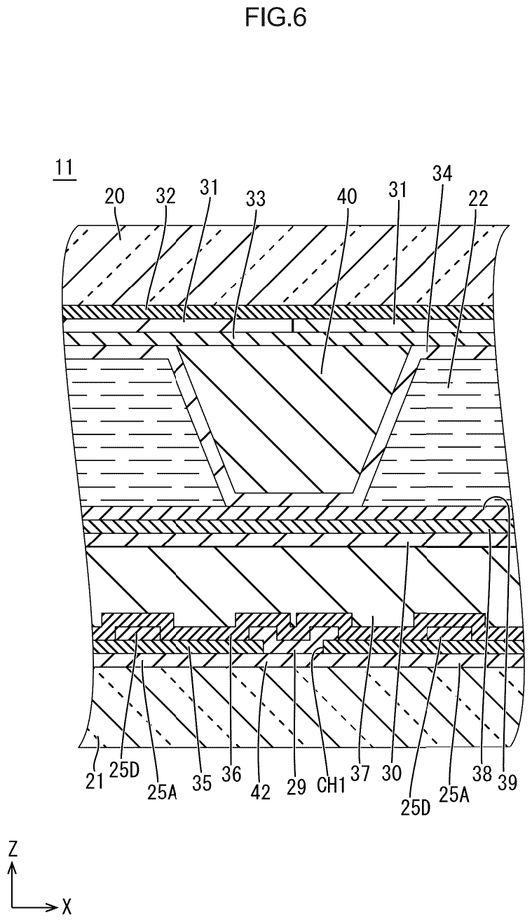

FIG. 6 is a cross-sectional typical view along vi-vi line in FIG. 3. As illustrated in FIGS. 3 and 6, spacers 40 are disposed in the display area AA of the opposed substrate 20 and project toward the array substrate 21 along the Z-axis direction. The pacers 40 are contacted with the second alignment film 39 of the array substrate 21 to keep a space between the substrates 20, 21, which is a cell gap (a thickness of the liquid crystal layer 22), to be a predefined dimension or greater. The spacers 40 are disposed to overlap intersections of the gate lines 27 and the source lines 28 and intersections of the gate lines 27 and the control lines 29. The number of the spacers 40 is equal to a total of the number of the intersections of the gate lines 27 and the source lines 28 and the number of intersections of the gate lines 27 and the control lines 29. The spacers 40 are made of organic material such as acrylic resin (PMMA) and have a thickness that is about same as a thickness of the planarization film 37. The spacers 40 include two kinds of spacers 40 that have different projecting dimensions. The two kinds of spacers 40 include main spacers 40 having a relatively great projecting dimension and sub spacers 40 having a relatively small projecting dimension. Projecting end surfaces of the main spacers 40 are always contacted with the second alignment film 39 of the array substrate 21. A clearance is between projecting end surfaces of the sub spacers 40 and the second alignment film 39 of the array substrate 21 such that one of the substrates 20, 21 can be warped (deformed).

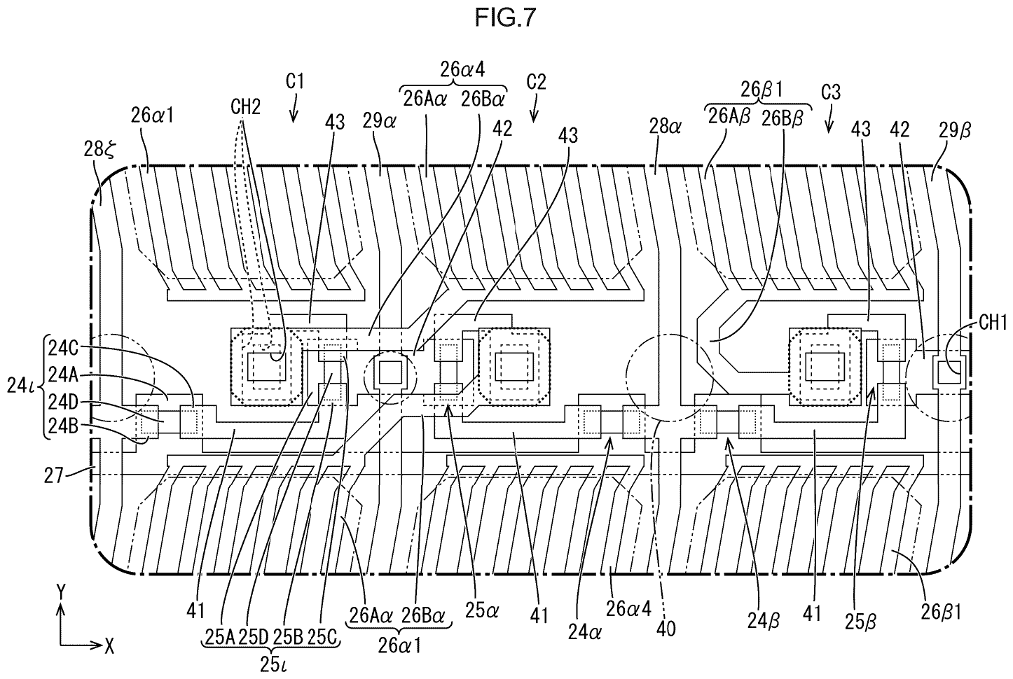

Next, configurations of the TFTs 24, 25 will be described. FIG. 7 is a plan view illustrating a first area A1 in FIG. 3. As illustrated in FIG. 5, the first TFT 24 includes a first gate electrode 24A (a first electrode), a first source electrode 24B (a second electrode), a first drain electrode 24C (a third electrode), and a first semiconductor section 24D. As illustrated in FIG. 7, the first TFT 24 is closer to the source line 28 than the control line 29 (the second TFT 25) with respect to the X-axis direction. With such a configuration, the distance between the first source electrode 24B of the first TFT 24 and the source line 28 that is connected to the first source electrode 24B can be reduced compared to a configuration in which the first TFT is closer to the control line 29 than the source line 28. Accordingly, delay due to parasitic capacitance and electric resistance is less likely to be caused in signals that are supplied to the first source electrode 24B from the source line 28. The first TFT 24 is closer to the gate line 27 (specifically, the gate line 27 to be connected to the first TFT 24) than the second TFT 25 is with respect to the Y-axis direction.

As illustrated in FIG. 5, the first gate electrode 24A is a portion of the first metal film. As illustrated in FIG. 7, the first gate electrode 24A is a wide section of the gate line 27 that extends along the X-axis direction. Specifically, the first gate electrode 24A projects upward in FIG. 7 from a portion of the gate line 27 that is adjacent to an intersection of the gate line 27 and the source line 28. Scan signals transmitted through the gate line 27 are supplied to the first gate electrode 24A.

As illustrated in FIG. 5, the first source electrode 24B is a portion of the second metal film. As illustrated in FIG. 7, the first source electrode 24B is a wide section of the source line 28 that extends along the Y-axis direction. Specifically, the first source electrode 24B projects leftward or rightward in FIG. 7 along the X-axis direction from a portion of the source line 28 that is adjacent to an intersection of the source line 28 and the gate line 27. A distal end portion of the first source electrode 24B projecting from the source line 28 overlaps the first gate electrode 24A as illustrated in FIG. 5.

As illustrated in FIG. 5, the first drain electrode 24C is a portion of the second metal film. The first drain electrode 24C is away from the first source electrode 24B with respect to the X-axis direction. One end portion of the first drain electrode 24C that is closer to the first source electrode 24B with respect to the X-axis direction overlaps the first gate electrode 24A. Another end portion of the first drain electrode 24C opposite from the one end portion overlaps a relay line section 41.

As illustrated in FIG. 5, the relay line section 41 is a portion of the second metal film and directly continuous to the first drain electrode 24C. As illustrated in FIG. 7, the relay line section 41 extends along the X-axis direction and a first end portion of the relay line section 41 (closer to the source line 28) is connected to the first drain electrode 24C and a second end portion of the relay line section 41 (closer to the control line 29) is connected to a second source electrode 25B. Thus, the relay line section 41 connects the first TFT 24 and the second TFT 25. The relay line section 41 is narrower than the first drain electrode 24C and the second source electrode 25B that are targets to be connected.

As illustrated in FIG. 5, the first semiconductor section 24D is a portion of the semiconductor film. The first semiconductor section 24D overlaps the first gate electrode 24A, which is a portion of the first metal film, via the gate insulating film 35. The first semiconductor section 24D is in a layer upper than the first gate electrode 24A. The first semiconductor section 24D is insulated from the first gate electrode 24A by the gate insulating film 35. The first semiconductor section 24D extends along the X-axis direction and one end portion of the first semiconductor section 24D (closer to the source line 28) is connected to the first source electrode 24B and other end portion of the first semiconductor section 24D (closer to the control line 29) is connected to the first drain electrode 24C. With a potential higher than the threshold voltage of the first TFT 24 being supplied to the first gate electrode 24A from the gate line 27 as a scanning signal, a channel section is created in the first semiconductor section 24D. Therefore, electrons move between the first source electrode 24B and the first drain electrode 24C via the channel section.

As illustrated in FIG. 5, the second TFT 25 includes a second gate electrode 25A (a fourth electrode), a second source electrode 25B (a fifth electrode), a second drain electrode 25C (a sixth electrode), and a second semiconductor section 25D. As illustrated in FIG. 7, the second TFT 25 is closer to the control line 29 than the source line 28 (the first TFT 24) with respect to the X-axis direction. With such a configuration, the distance between the second gate electrode 25A of the second TFT 25 and the control line 29 that is connected to the second gate electrode 25A can be reduced compared to a configuration in which the second TFT is closer to the source line 28 than the control line 29. Accordingly, delay due to parasitic capacitance and electric resistance is less likely to be caused in signals that are supplied to the second gate electrode 25A from the control line 29. The second TFT 25 is farther from the gate line 27 (specifically, the gate line 27 to be connected to the first TFT 24) than the first TFT 24 is with respect to the Y-axis direction.

As illustrated in FIG. 5, the second gate electrode 25A is a portion of the first metal film. The second gate electrode 25A is disposed away from a portion of the control line 29 that is adjacent to an intersection of the control line 29 and the gate line 27 in the X-axis direction. The second gate electrode 25A is connected to a connection electrode 42.

As illustrated in FIG. 6, the connection electrode 42 is a portion of the first metal film and is continuous to the second gate electrode 25A. As illustrated in FIG. 7, the connection electrode 42 extends along the X-axis direction and crosses the control line 29. Two end portions of the connection electrode 42 with respect to the X-axis direction are connected to the second gate electrodes 25A of two second TFTs 25, respectively. The two second TFTs 25 that are connected to one connection electrode 42 are disposed to sandwich the control line 29 therebetween in the X-axis direction. The gate insulating film 35 that is disposed between the connection electrode 42 and the control line 29 includes a first contact hole CH1 in a portion thereof overlapping the connection electrode 42 and the control line 29, as illustrated in FIG. 6. The connection electrode 42 and the control line 29 that are overlapped with each other are connected via the first contact hole CH1. Control signals transmitted through the control line 29 are supplied to the second gate electrode 25A via the connection electrode 42.

As illustrated in FIG. 5, the second source electrode 25B is a portion of the second metal film and is directly continuous to the relay line section 41. As illustrated in FIG. 7, the second source electrode 25B extends along the Y-axis direction from the second end portion of the relay line section 41 toward an opposite side from the gate line 27. A distal end portion of the second source electrode 25B projecting from the relay line section 41 overlaps the second gate electrode 25A.

As illustrated in FIG. 5, the second drain electrode 25C is a portion of the second metal film. The second drain electrode 25C is away from the second source electrode 25B in the Y-axis direction. A portion of the second drain electrode 25C close to the second source electrode 25B in the X-axis direction overlaps the second gate electrode 25A. A portion of the second drain electrode 25C that is an opposite-side portion from the second source electrode 25B in the Y-axis direction is connected to a drain line section 43.

As illustrated in FIG. 5, the drain line section 43 is a portion of the second metal film and is directly continuous to the second drain electrode 25C. As illustrated in FIG. 7, the drain line section 43 extends along the X-axis direction from the opposite-side portion of the second drain electrode 25C toward the source line 28 and thereafter extends toward the gate line 27 along the Y-axis direction. An opposite-side portion of the drain line section 43 that is opposite from the second drain electrode 25C is a wide section that is wider than other portion and the wide section overlaps the end portion of the connection line portion 26B of the pixel electrode 26. As illustrated in FIG. 5, the first interlayer insulating film 36, the planarization film 37, and the second interlayer insulation film 38 that are disposed between the drain line section 43 and the connection line portion 26B include second contact holes CH2 in portions overlapping the drain line section 43 and the connection line portion 26B. The drain line section 43 and the connection line portion 26B that are overlapped with each other are connected via the second contact holes CH2. Thus, the drain line section 43 connects the second drain electrode 25C and the pixel electrode 26. The drain line section 43 may be a portion of the second drain electrode 25C.

As illustrated in FIG. 5, the second semiconductor section 25D is a portion of the semiconductor film. The second semiconductor section 25D overlaps the second gate electrode 25A, which is a portion of the first metal film, via the gate insulating film 35. The second semiconductor section 25D is in a layer upper than the second gate electrode 25A. The second semiconductor section 25D is insulated from the second gate electrode 25A by the gate insulating film 35. As illustrated in FIG. 7, the second semiconductor section 25D extends along the Y-axis direction and one end portion of the second semiconductor section 25D (closer to the gate line 27) is connected to the second source electrode 25B and other end portion of the second semiconductor section 25D (closer to the body portion 26A) is connected to the second drain electrode 25C. With a potential higher than the threshold voltage of the second TFT 25 being supplied to the second gate electrode 25A from the control line 29 as a scanning signal, a channel section is created in the second semiconductor section 25D. Therefore, electrons move between the second source electrode 25B and the second drain electrode 25C via the channel section.

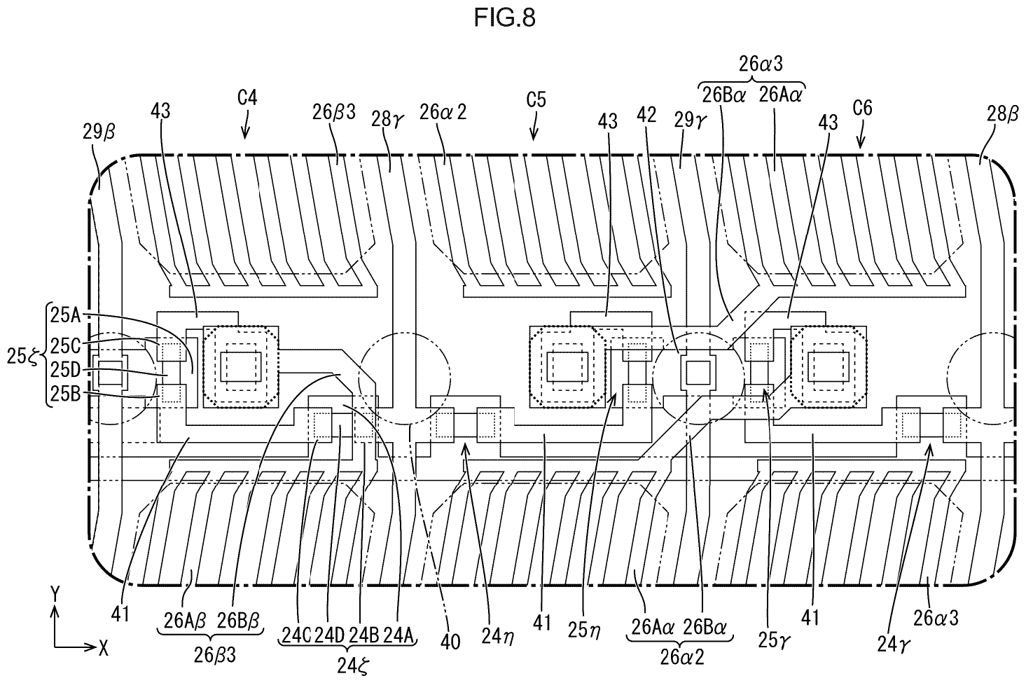

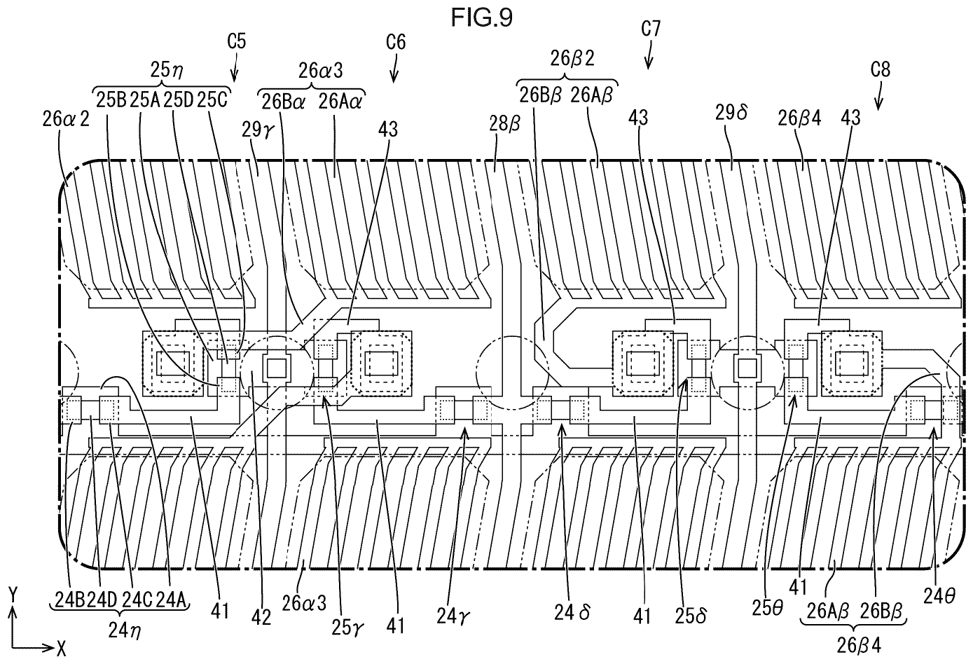

As illustrated in FIGS. 7 to 10, the pixel electrodes 26 according to this embodiment include first pixel electrodes 26α and second pixel electrodes 26B. Hereinafter, the body portions 26A and the connection line portions 26B of the first pixel electrodes 26α are defined as first body portions 26Aα and first connection line portions 26Bα. The body portions 26A and the connection line portions 26B of the second pixel electrodes 26β are defined as second body portions 26Aβ and second connection line portions 26Bβ. FIG. 8 is a plan view illustrating a second area A2 in FIG. 3. FIG. 9 is a plan view illustrating a third area A3 in FIG. 3.

As illustrated in FIGS. 7 to 9, the first connection line portion 26Bα of the first pixel electrode 26α is disposed to cross the control line 29 or the source line 28. The first body portion 26Aα of the first pixel electrode 26α and the second TFT 25 that is connected to the first connection line portion 26Bα sandwich the control line 29 or the source line 28. Therefore, the first body portion 26Aα of the first pixel electrode 26α is connected via the first connection line portion 26Bα to the second TFT 25 that is included in a pixel column different from a pixel column including the first body portion 26Aα. On the other hand, the second connection line portion 26Bβ of the second pixel electrode 26β is disposed not to cross the control line 29 and the source line 28. Therefore, the second body portion 26Aβ of the second pixel electrode 26β is connected via the second connection line portion 26Bβ to the second TFT 25 that is included in the pixel column that includes the second body portion 26Aβ.

As previously described, as illustrated in FIGS. 7 to 9, the first pixel electrode 26α includes the first connection line portion 26Bα that is connected to the first body portion 26Aα and the second drain electrode 25C of the second TFT 25 and the first connection line portion 26Bα crosses the source line 28 or the control line 29. With the first connection line portion 26Bα crossing the source line 28 or the control line 29, variation of the arrangement of the first body portion 26Aα of the first pixel electrode 26α is increased. The first pixel electrode 26α can be connected to the second TFT 25 that is included in a pixel column different from the pixel column including the first body portion 26Aα of the first pixel electrode 26α. With the variation of the arrangement of the first body portion 26Aα of the first pixel electrode 26α being increased, following effects are obtained. If image signals whose polarity is not inverted in a certain frame display period and inverted in every frame display period are supplied to each source line 28, every two columns of the pixels having a same polarity are not arranged alternately. Therefore, display errors of stripes are less likely to be seen compared to the display device in which the arrangement of the pixel electrodes is fixed. Therefore, power consumption can be reduced with keeping display quality.

As illustrated in FIGS. 7 to 9, with respect to the first pixel electrode 26α and the second pixel electrode 26β, the areas of the first body portion 26Aα and the second body portion 26Aβ are same (substantially same) and the areas of the first connection line portion 26Bα and the second connection line portion 26Bβ are same (substantially same). Namely, the areas of the first pixel electrode 26α and the second pixel electrode 26β are same (substantially same) and therefore, an electrostatic capacitance (electric field intensity) created between the first pixel electrode 26α and the common electrode 30 is equal (substantially equal) to an electrostatic capacitance (electric field intensity) created between the second pixel electrode 26β and the common electrode 30. Accordingly, display unevenness is less likely to be caused between the pixels PX including the first pixel electrodes 26α and the pixels PX including the second pixel electrodes 26β.

As illustrated in FIGS. 7 to 9, with respect to the first pixel electrode 26α and the second pixel electrode 26β, the length of the first connection line portion 26Bα extending from the first body portion 26Aα to the drain line section 43 (the second drain electrode 25C) is same (substantially same) as the length of the second connection line portion 26Bβ extending from the second body portion 26Aβ to the drain line section 43. With such a configuration including the same lengths of the first connection line portion 26Bα and the second connection line portion 26Bβ, even if the widths of the first connection line portion 26Bα and the second connection line portion 26Bβ are varied due to the manufacturing reasons, difference in the areas of the first connection line portion 26Bα and the second connection line portion 26Bβ is less likely to be caused. Accordingly, display unevenness is less likely to be caused.

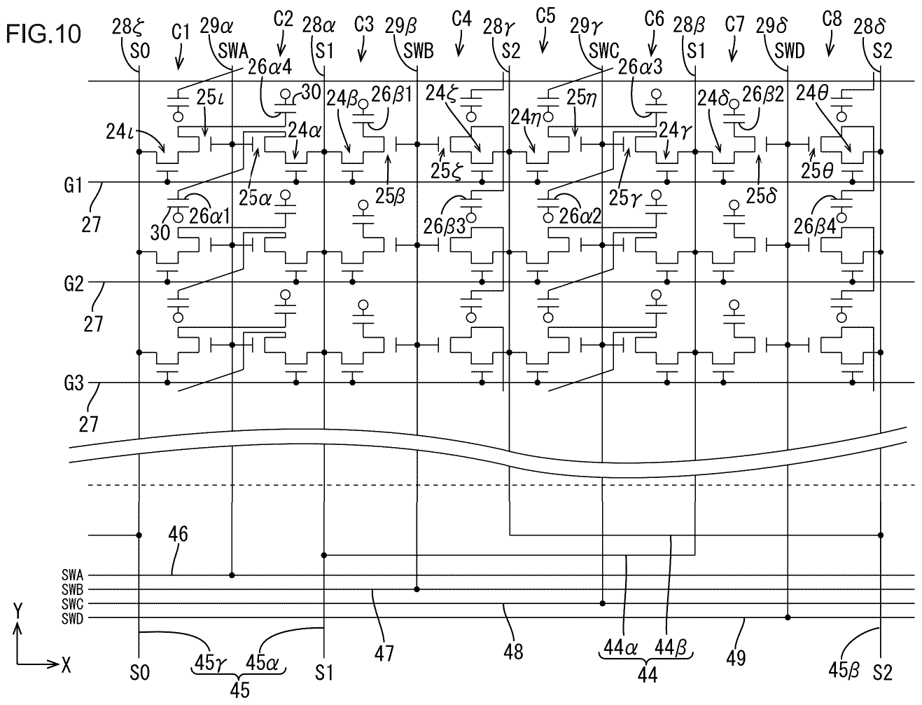

Hereinafter, a left end one of the control lines 29 in FIGS. 3 and 10 is defined as a first control line 29α, a second one of the control lines 29 from the left end in FIGS. 3 and 10 is defined as a second control line 29β, a third one of the control lines 29 from the left end in FIGS. 3 and 10 is defined as a third control line 29γ, and a fourth one of the control lines 29 from the left end in FIGS. 3 and 10 is defined as a fourth control line 298.

One of the source lines 28 that is between the first control line 29α and the second control line 29β with respect to the X-axis direction is defined as a first source line 28α. One of the source lines 28 that is between the third control line 29γ and the fourth control line 29δ with respect to the X-axis direction is defined as a second source line 28β. One of the source lines 28 that is between the second control line 29β and the third control line 29γ with respect to the X-axis direction is defined as a third source line 28γ. One of the source lines 28 that is on an opposite side from the second source line 28β with respect to the fourth control line 29δ in the X-axis direction is defined as a fourth source line 28δ. One of the source lines 28 that is on an opposite side from the first source line 28α with respect to the first control line 29α is defined as a fifth source line 28ζ.

One of the first TFTs 24 including the first source electrode 24B that is connected to the first source line 28α is defined as a first signal TFT 24α (a first signal switching component) and another one of the first TFTs 24 including the first source electrode 24B that is connected to the first source line 28α is defined as a second signal TFT 24β (a second signal switching component). One of the first TFTs 24 including the first source electrode 24B that is connected to the second source line 28β is defined as a third signal TFT 24γ (a third signal switching component) and another one of the first TFTs 24 including the first source electrode 24B that is connected to the second source line 28β is defined as a fourth signal TFT 24δ (a fourth signal switching component). One of the first TFTs 24 including the first source electrode 24B that is connected to the third source line 28γ is defined as a fifth signal TFT 24ζ (a fifth signal switching component) and another one of the first TFTs 24 including the first source electrode 24B that is connected to the third source line 28γ is defined as a sixth signal TFT 24η (a sixth signal switching component). One of the first TFTs 24 including the first source electrode 24B that is connected to the fourth source line 28δ is defined as a seventh signal TFT 24θ (a seventh signal switching component) and another one of the first TFTs 24 including the first source electrode 24B that is connected to the fourth source line 28δ is defined as an eighth signal TFT 241 (an eighth signal switching component).

One of the second TFTs 25 that includes the second gate electrode 25A connected to the first control line 29α and the second source electrode 25B connected to the first drain electrode 24C of the first signal TFT 24α is defined as a first control TFT 25α (a first control switching component). One of the second TFTs 25 that includes the second gate electrode 25A connected to the second control line 29β and the second source electrode 25B connected to the first drain electrode 24C of the second signal TFT 24β is defined as a second control TFT 25β (a second control switching component). One of the second TFTs 25 that includes the second gate electrode 25A connected to the third control line 29γ and the second source electrode 25B connected to the first drain electrode 24C of the third signal TFT 24γ is defined as a third control TFT 25γ (a third control switching component). One of the second TFTs 25 that includes the second gate electrode 25A connected to the fourth control line 29δ and the second source electrode 25B connected to the first drain electrode 24C of the fourth signal TFT 24δ is defined as a fourth control TFT 25δ (a fourth control switching component). One of the second TFTs 25 that includes the second gate electrode 25A connected to the second control line 29β and the second source electrode 25B connected to the first drain electrode 24C of the fifth signal TFT 24ζ is defined as a fifth control TFT 25ζ (a fifth control switching component). One of the second TFTs 25 that includes the second gate electrode 25A connected to the third control line 29γ and the second source electrode 25B connected to the first drain electrode 24C of the sixth signal TFT 24η is defined as a sixth control TFT 25η (a sixth control switching component). One of the second TFTs 25 that includes the second gate electrode 25A connected to the fourth control line 29δ and the second source electrode 25B connected to the first drain electrode 24C of the seventh signal TFT 24θ is defined as a seventh control TFT 25θ (a seventh control switching component). One of the second TFTs 25 that includes the second gate electrode 25A connected to the first control line 29α and the second source electrode 25B connected to the first drain electrode 24C of the eighth signal TFT 24ι is defined as an eighth control TFT 25ι (an eighth control switching component).

In this embodiment, among the second TFTs 25, the first control TFT 25α, the third control TFT 25γ, the sixth control TFT 25η, and the eighth control TFT 251 are connected to the first pixel electrodes 26α, respectively. One of the first pixel electrodes 26α that is connected to the first control TFT 25α is defined as a first pixel electrode 26α1. One of the first pixel electrodes 26α that is connected to the third control TFT 25γ is defined as a first pixel electrode 26α2. One of the first pixel electrodes 26α that is connected to the sixth control TFT 25η is defined as a first pixel electrode 26α3. One of the first pixel electrodes 26α that is connected to the eighth control TFT 25ι is defined as a first pixel electrode 26α4.

Among the second TFTs 25, the second control TFT 25B, the fourth control TFT 258, the fifth control TFT 25ζ, and the seventh control TFT 25θ are connected to the second pixel electrodes 26β. One of the second pixel electrodes 26β that is connected to the second control TFT 25B is defined as a second pixel electrode 26β1. One of the second pixel electrodes 26β that is connected to the fourth control TFT 25δ is defined as a second pixel electrode 26β2. One of the second pixel electrodes 26β that is connected to the fifth control TFT 25ζ is defined as a second pixel electrode 26β3. One of the second pixel electrodes 26β that is connected to the seventh control TFT 25θ is defined as a second pixel electrode 26β4.

As illustrated in FIG. 7, the first body portion 26Aα of the first pixel electrode 26α1 that is connected to the first control TFT 25α is disposed between the fifth source line 285 and the first control line 29α with respect to the X-axis direction. The first body portion 26Aα of the first pixel electrode 26α1 is included in a pixel column that is adjacent to the pixel column including the first control TFT 25α such that the two pixel columns sandwich the first control line 29α. Namely, the first body portion 26Aα of the first pixel electrode 26α1 that is connected to the first control TFT 25α is included in a first pixel column C1 that is a first column from the left end in FIGS. 3 and 10. Most portion of the first body portion 26Aα of the first pixel electrode 26α1 is disposed on a lower side of the first control TFT 25α in FIG. 7 with respect to the Y-axis direction with having the gate line 27 therebetween. The pixel row including the first body portion 26Aα of the first pixel electrode 26α1 is next to the pixel row including the first control TFT 25α with sandwiching the gate line 27 therebetween. The first connection line portion 26Bα of the first pixel electrode 26α1 extends from the first body portion 26Aα, which is a target to be connected, to the drain line section 43 connected to the second drain electrode 25C of the first control TFT 25α with crossing the first control line 29α. Specifically, the first connection line portion 26Bα of the first pixel electrode 26α1 extends from the drain line section 43, which is a target to be connected, along the X-axis direction toward the first control line 29α and further extends obliquely with respect to the X-axis direction and the Y-axis direction to the first body portion 26Aα, which is a target to be connected, with crossing the first control line 29α.

As illustrated in FIG. 7, the second body portion 26Aβ of the second pixel electrode 26β1 that is connected to the second control TFT 25β is disposed between the first source line 28α and the second control line 29β with respect to the X-axis direction. The second body portion 26Aβ of the second pixel electrode 26β1 is included in a pixel column that includes the second control TFT 25β. Namely, the second body portion 26Aβ of the second pixel electrode 26β1 that is connected to the second control TFT 25β is included in a third pixel column C3 that is a third one from the left end in FIGS. 3 and 10. The second body portion 26Aβ of the second pixel electrode 26β1 is disposed adjacent to the second control TFT 25β without having the gate line 27 therebetween with respect to the Y-axis direction. The second body portion 26Aβ of the second pixel electrode 26β1 is included in the pixel row that includes the second control TFT 25β. The second connection line portion 26Bβ of the second pixel electrode 26β1 extends from the second body portion 26Aβ, which is a target to be connected, to the drain line section 43 connected to the second drain electrode 25C of the second control TFT 25β without crossing the source line 28 and the control line 29. Specifically, the second connection line portion 26Bβ of the second pixel electrode 26β1 extends from the drain line section 43, which is a target to be connected, along the X-axis direction toward the first source line 28α and further extends with being curved in a U-shape to the second body portion 26Aβ, which is a target to be connected. Thus, the second connection line portion 26Bβ of the second pixel electrode 26β1 has a curved U-shape as a whole.

As illustrated in FIG. 7, the first body portion 26Aα of the first pixel electrode 26α4 that is connected to the eighth control TFT 251 is disposed between the first control line 29α and the first source line 28α with respect to the X-axis direction. The first body portion 26Aα of the first pixel electrode 26α4 is included in a pixel column that is adjacent to the pixel column including the eighth control TFT 25ι such that the two pixel columns sandwich the first control line 29α. Namely, the first body portion 26Aα of the first pixel electrode 26α4 that is connected to the eighth control TFT 25ι is included in a second pixel column C2 that is a second one from the left end in FIGS. 3 and 10. The first body portion 26Aα of the first pixel electrode 26α4 and the eighth control TFT 25ι do not sandwich the gate line 27 with respect to the Y-axis direction and the first body portion 26Aα of the first pixel electrode 26α4 is included in a pixel row that includes the eighth control TFT 25ι. The first connection line portion 26Bα of the first pixel electrode 26α4 extends from the first body portion 26Aα, which is a target to be connected, to the drain line section 43 connected to the second drain electrode 25C of the eighth control TFT 251 with crossing the first control line 29α. Specifically, the first connection line portion 26Bα of the first pixel electrode 26α4 extends from the drain line section 43, which is a target to be connected, along the X-axis direction toward the first control line 29α and crosses the first control line 29α and further extends obliquely with respect to the X-axis direction and the Y-axis direction to the first body portion 26Aα, which is a target to be connected.

As illustrated in FIG. 8, the first body portion 26Aα of the first pixel electrode 26α2 that is connected to the third control TFT 25γ is disposed between the third source line 28γ and the third control line 29γ with respect to the X-axis direction. The first body portion 26Aα of the first pixel electrode 26α2 is included in a pixel column that is adjacent to the pixel column including the third control TFT 25γ such that the two pixel columns sandwich the third control line 29γ. Namely, the first body portion 26Aα of the first pixel electrode 26α2 that is connected to the third control TFT 25γ is included in a fifth pixel column C5 that is a fifth one from the left end in FIGS. 3 and 10. Most portion of the first body portion 26Aα of the first pixel electrode 26α2 is disposed on a lower side of the third control TFT 25γ in FIG. 7 with respect to the Y-axis direction with sandwiching the gate line 27 therebetween. The pixel row including the first body portion 26Aα of the first pixel electrode 26α2 is next to the pixel row including the third control TFT 25γ with sandwiching the gate line 27 therebetween. The first connection line portion 26Bα of the first pixel electrode 26α2 extends from the first body portion 26Aα, which is a target to be connected, to the drain line section 43 connected to the second drain electrode 25C of the third control TFT 25γ with crossing the third control line 29γ. Specifically, the first connection line portion 26Bα of the first pixel electrode 26α2 extends from the drain line section 43, which is a target to be connected, along the X-axis direction toward the third control line 29γ and further extends obliquely with respect to the X-axis direction and the Y-axis direction to the first body portion 26Aα, which is a target to be connected, with crossing the first control line 29α. The first connection line portion 26Bα of the first pixel electrode 26α2 and the first connection line portion 26Bα of the first pixel electrode 26α1 have a substantially same plan view shape and have a substantially same width and a substantially same area.

As illustrated in FIG. 8, the second body portion 26Aβ of the second pixel electrode 26β3 that is connected to the fifth control TFT 25ζ is disposed between the second control line 29β and the third source line 28γ with respect to the X-axis direction. The second body portion 26Aβ of the second pixel electrode 26β3 is included in the pixel column that includes the fifth control TFT 25ζ. Namely, the second body portion 26Aβ of the second pixel electrode 26β3 that is connected to the fifth control TFT 25ζ is included in a fourth pixel column C4 that is a fourth one from the left end in FIGS. 3 and 10. Most portion of the second body portion 26Aβ of the second pixel electrode 26β3 is disposed on a lower side of the fifth control TFT 25ζ in FIG. 8 with respect to the Y-axis direction with sandwiching the gate line 27 therebetween. The pixel row including the second body portion 26Aβ of the second pixel electrode 26β3 is next to the pixel row including the fifth control TFT 25ζ with sandwiching the gate line 27 therebetween. The second connection line portion 26Bβ of the second pixel electrode 26β3 extends from the second body portion 26Aβ, which is a target to be connected, to the drain line section 43 connected to the second drain electrode 25C of the fifth control TFT 25ζ without crossing the source line 28 and the control line 29. Specifically, the second connection line portion 26Bβ of the second pixel electrode 26β3 extends from the drain line section 43, which is a target to be connected, along the X-axis direction toward the third source line 28γ and is curved and further extends along the Y-axis direction and crosses at least a portion of the gate line 27 and extends to the second body portion 26Aβ, which is a target to be connected. Thus, the second connection line portion 26Bβ of the second pixel electrode 26β3 has a L-shape as a whole.

As illustrated in FIG. 8, the first body portion 26Aα of the first pixel electrode 26α3 that is connected to the sixth control TFT 25η is disposed between the third control line 29γ and the second source line 28β with respect to the X-axis direction. The first body portion 26Aα of the first pixel electrode 26α3 is included in a pixel column that is adjacent to the pixel column including the sixth control TFT 25η such that the two pixel columns sandwich the third control line 29γ. Namely, the first body portion 26Aα of the first pixel electrode 26α3 that is connected to the sixth control TFT 25η is included in a sixth pixel column C6 that is a sixth one from the left end in FIGS. 3 and 10. The first body portion 26Aα of the first pixel electrode 26α3 and the sixth control TFT 25η do not sandwich the gate line 27 with respect to the Y-axis direction and is included in a pixel row that includes the sixth control TFT 25η. The first connection line portion 26Bα of the first pixel electrode 26α3 extends from the first body portion 26Aα, which is a target to be connected, to the drain line section 43 connected to the second drain electrode 25C of the sixth control TFT 25η with crossing the third control line 29γ. Specifically, the first connection line portion 26Bα of the first pixel electrode 26α3 extends from the drain line section 43, which is a target to be connected, along the X-axis direction toward the third control line 29γ and crosses the third control line 29γ and further extends obliquely with respect to the X-axis direction and the Y-axis direction to the first body portion 26Aα, which is a target to be connected. The first connection line portion 26Bα of the first pixel electrode 26α3 and the first connection line portion 26Bα of the first pixel electrode 26α4 have a substantially same plan view shape and have a substantially same width and a substantially same area.

As illustrated in FIG. 9, the second body portion 26Aβ of the second pixel electrode 26β2 that is connected to the fourth control TFT 25δ is disposed between the second source line 28β and the fourth control line 29δ with respect to the X-axis direction. The second body portion 26Aβ of the second pixel electrode 26β2 is included in a pixel column that includes the fourth control TFT 25δ. Namely, the second body portion 26Aβ of the second pixel electrode 26β2 that is connected to the fourth control TFT 25δ is included in a seventh pixel column C7 that is a seventh one from the left end in FIGS. 3 and 10. The second body portion 26Aβ of the second pixel electrode 26β2 is disposed adjacent to the second control TFT 25B with respect to the Y-axis direction without having the gate line 27 therebetween. The second body portion 26Aβ of the second pixel electrode 26β2 is included in the pixel row that includes the fourth control TFT 25δ. The second connection line portion 26Bβ of the second pixel electrode 26β2 extends from the second body portion 26Aβ, which is a target to be connected, to the drain line section 43 connected to the second drain electrode 25C of the fourth control TFT 258 without crossing the source line 28 and the control line 29. Specifically, the second connection line portion 26Bβ of the second pixel electrode 26β2 extends from the drain line section 43, which is a target to be connected, along the X-axis direction toward the second source line 28β and further extends with being curved in a U-shape to the second body portion 26Aβ, which is a target to be connected. Thus, the second connection line portion 26Bβ of the second pixel electrode 26β2 has a curved U-shape as a whole. The second connection line portion 26Bβ of the second pixel electrode 26β2 and the second connection line portion 26Bβ of the second pixel electrode 26β1 have a substantially same plan view shape and have a substantially same width and a substantially same area.

As illustrated in FIG. 3, the second body portion 26Aβ of the second pixel electrode 26β4 that is connected to the seventh control TFT 25θ is disposed between the fourth control line 29δ and the fourth source line 28δ with respect to the X-axis direction. The second body portion 26Aβ of the second pixel electrode 26β4 is included in a pixel column that includes the seventh control TFT 25θ as illustrated in FIG. 8. Namely, the second body portion 26Aβ of the second pixel electrode 26β4 that is connected to the seventh control TFT 25θ is included in an eighth pixel column C8 that is an eighth one from the left end in FIGS. 3 and 10. Most portion of the second body portion 26Aβ of the second pixel electrode 26β4 is disposed on a lower side of the seventh control TFT 25θ in FIG. 8 with respect to the Y-axis direction with sandwiching the gate line 27 therebetween. The pixel row including the second body portion 26Aβ of the second pixel electrode 26β4 is next to the pixel row including the seventh control TFT 25θ with sandwiching the gate line 27 therebetween. The second connection line portion 26Bβ of the second pixel electrode 26β4 extends from the second body portion 26Aβ, which is a target to be connected, to the drain line section 43 connected to the second drain electrode 25C of the seventh control TFT 25θ without crossing the source line 28 and the control line 29. Specifically, the second connection line portion 26Bβ of the second pixel electrode 26β4 extends from the drain line section 43, which is a target to be connected, along the X-axis direction toward the fourth source line 28δ and is curved and further extends along the Y-axis direction and crosses at least a portion of the gate line 27 and extends to the second body portion 26Aβ, which is a target to be connected. Thus, the second connection line portion 26Bβ of the second pixel electrode 26β4 has a L-shape as a whole. The second connection line portion 26Bβ of the second pixel electrode 26β4 and the second connection line portion 26Bβ of the second pixel electrode 26β3 have a substantially same plan view shape and have a substantially same width and a substantially same area.

As illustrated in FIG. 10, a short circuit line 44 that connects two source lines 28 to cause a short circuit therebetween, an extending line 45 extending from the source line 28 to the driver 12, and control main lines 46 to 48 that are connected to the control lines 29, respectively, are disposed in the non-display area NAA of the array substrate 21. As illustrated in FIG. 1, the short circuit lines 44, the extending lines 45, and the control main lines 46 to 48 are disposed between the display area AA and the drivers 12 with respect to the Y-axis direction.

As illustrated in FIG. 10, the short circuit line 44 extends along the X-axis direction and two ends of the short circuit line 44 are connected to the two source lines 28, which are targets to be connected, respectively. The short circuit line 44 crosses two control lines 29 and the source line 28 that is not a target to be connected. The short circuit lines 44 include one short circuit line 44 that is connected to a nth source line 28 and a (n+2)th source line 28 from the left end in FIG. 10 and another short circuit line 44 that is connected to a (n+1)th source line 28 and a (n+3)th source line 28 from the left end in FIG. 10 (n: natural number). The short circuit line 44 may be a portion of the first metal film. In such a configuration, the gate insulating film 35 includes a contact hole in a portion overlapping the short circuit line 44 and the source line 28, which is a target to be connected, for connecting the short circuit line 44 and the target source line 28. With the short circuit line 44 being a portion of the first metal film, the gate insulating film 35 prevents short circuits from occurring between the short circuit line 44 and the source line 28 that crosses the short circuit line 44 and between the short circuit line 44 and the control line 29 that crosses the short circuit line 44.

Hereinafter, one of the short circuit lines 44 that is connected to the first source line 28α and the second source line 28β is defined as a first short circuit line 44α and another one of the short circuit lines 44 that is connected to the third source line 28γ and the fourth source line 28δ is defined as a second short circuit line 44B.

As illustrated in FIG. 10, the extending lines 45 extend along the Y-axis direction and one ends of the extending lines 45 are connected to the source lines 28, respectively, and other ends are connected to the drivers 12 (refer to FIG. 1). In this embodiment, the extending line 45 is connected to one of the two source lines 28 that are connected by the short circuit line 44. The extending line 45 may be a portion of the second metal film. In such a configuration, the extending line 45 is directly continuous to the source line 28, which is a target to be connected. Image signals to be supplied to the two source lines 28 that are connected by the short circuit line 44 are supplied to the extending line 45 from the driver 12. Therefore, the number of lines in the area between the driver 12 and the display area AA in the non-display area NAA can be reduced compared to a configuration in which each of the first source line 28α and the second source line 28β is connected to the driver 12 without including the first short circuit line 44α. This preferably reduces a frame width of the device.

Hereinafter, one of the extending lines 45 that is connected to the first source line 28α is defined as a first extending line 45α, another one of the extending lines 45 that is connected to the fourth source line 28δ is defined as a second extending line 45β, and other one of the extending lines 45 that is connected to the fifth source line 28ζ is defined as a third extending line 45γ.

As illustrated in FIG. 10, the control main lines 46 to 49 extend along the X-axis direction in at least the area between the display area AA and the driver 12 and are arranged at intervals in the Y-axis direction. The control main lines 46 to 49 include a first control main line 46 connected to the first control line 29α, a second control main line 47 connected to the second control line 29β, a third control main line 48 connected to the third control line 29γ and a fourth control main line 49 connected to the fourth control line 29δ. Ends of the control main lines 46 to 49 are connected to terminals, respectively, that are connected to the flexible substrate 13. With such a configuration, the control main lines 46 to 49 are supplied with control signals from the control board 14 via the flexible substrate 13.

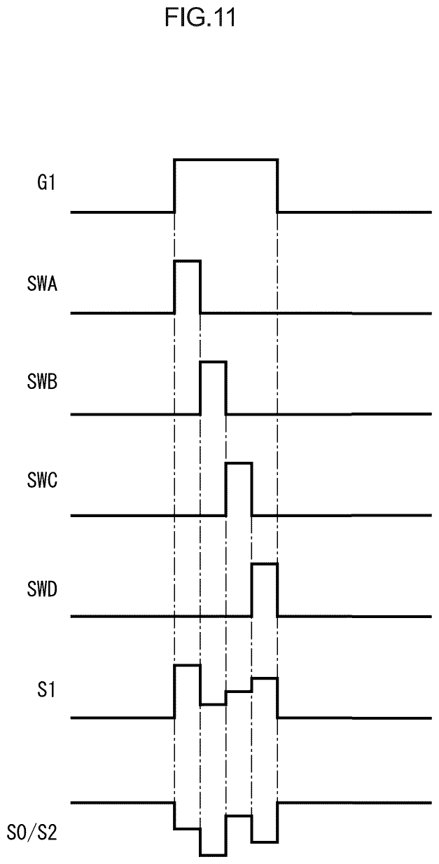

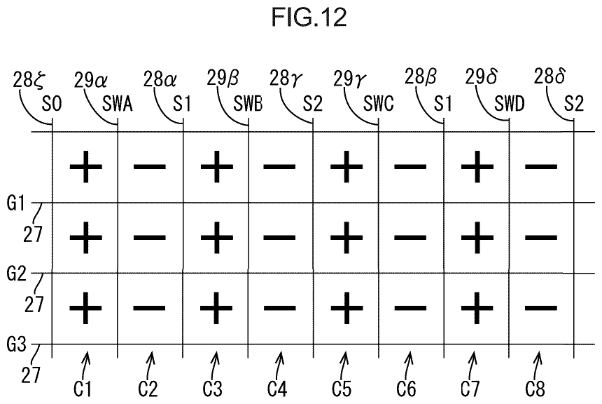

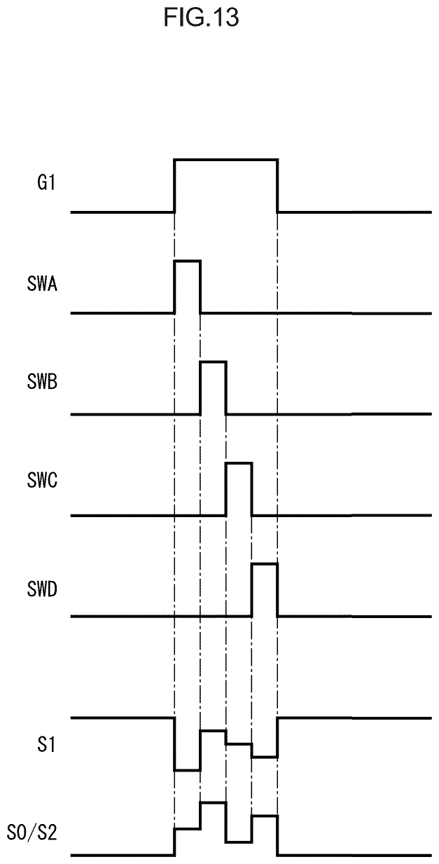

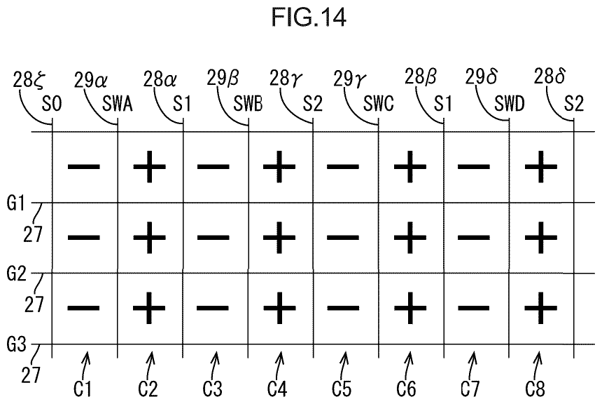

The present embodiment has the configuration described above and operations will be described with reference to FIGS. 10 to 14. FIGS. 11 and 13 illustrate waveforms of signals transmitted through the gate lines 27, the source lines 28α to 28ζ, and the control lines 29α to 29δ. FIG. 13 illustrates waveforms of signals outputted after one frame display period after the output of the signals illustrated in FIG. 11. Specifically, in FIGS. 11 and 13, a scanning signal G1 transmitted through the predefined gate line 27, a control signal SWA transmitted through the first control line 29α, a control signal SWB transmitted through the second control line 29β, a control signal SWC transmitted through the third control line 29γ, a control signal SWD transmitted through the fourth control line 29δ, an image signal S1 transmitted through the first source line 28α and the second source line 28B, and an image signal S2 (an image signal S0 transmitted through the fifth source line 28ζ) transmitted through the third source line 28γ and the fourth source line 28δ are illustrated in this order from the above. The image signal S0 transmitted through the fifth source line 28ζ has a same polarity as the image signal S2 transmitted through the third source line 28γ and the fourth source line 28δ. Therefore, in FIGS. 11 and 13, the image signals are described with “S0/S2”. The image signal S0 and the image signal S2 necessarily have a same polarity and voltages of the image signals S0, S2 in each period may be different. In FIGS. 12 and 14, the pixel electrodes 26α1 to 26α4, 26β1 to 26β4, the gate lines 27, the source lines 28α to 28ζ, and the control lines 29α to 29δ are typically illustrated and the positive polarity and the negative polarity of the image signals written in the pixel electrodes 26α1 to 26α4, 26β1 to 26β4 are illustrated with the symbols of “+” and “−”

As illustrated in FIGS. 1, 10, and 11, with potential of a high level (hereinafter, referred to as high potential) of the scanning signal G1 being supplied to the gate line 27 from the gate driver circuit 15, in synchronization therewith, high potential of the control signals SWA to SWD are supplied to the control lines 29α to 29δ from the control board 14 at different timings and the image signals S0 to S2 are supplied to the source lines 28α to 28ζ from the driver 12 in synchronization with the timing at which the control signals SWA to SWD are supplied to the control lines 29α to 29δ. The high potential is higher than the threshold voltage of the first TFT 24 and the second TFT 25. The period while the control signals SWA to SWD have the high potential is about one fourth of the period while the scanning signal G1 has the high potential. Namely, the period while the control signals SWA to SWD have the high potential is the reciprocal of the total number of the control signals SWA to SWD. The first source line 28α and the second source line 28β are supplied with the positive image signal S1. The third source line 28γ and the fourth source line 28δ are supplied with the negative image signal S2 and the fifth source line 28ζ is supplied with the negative image signal S0. Namely, the driver 12 supplies the image signal S1 and the image signals S0, S2 having opposite polarities. The control signals SWA to SWD outputted from the control board 14 are supplied to the control lines 29α to 29δ via the flexible substrate 13 and the control main lines 46 to 49. The image signal S1 outputted from the driver 12 is supplied to the first source line 28α and the second source line 28β via the first extending line 45α and the first short circuit line 44α. The image signal S2 outputted from the driver 12 is supplied to the third source 28γ and the fourth source line 28δ via the second extending line 45β and the second short circuit line 44β. The image signal S0 outputted from the driver 12 is supplied to the fifth source line 28ζ via the third extending line 45γ.

Specifically, as illustrated in FIGS. 10 and 11, with high potential of the scanning signal G1 being supplied to the gate line 27, all the first TFTs 24 included in the pixel row that includes the first TFTs 24 connected to the gate line 27 to which the scanning signal G1 is supplied are collectively driven. While high potential of the scanning signal G1 is supplied to the gate line 27, the high potential of the control signals SWA to SWD is supplied to the first control line 29α, the second control line 29β, the third control line 29γ, and the fourth control line 29δ in this order. Specifically, the rising edge timing of the high potential of the scanning signal G1 matches the rising edge timing of the high potential of the control signal SWA. The falling edge timing of the high potential of the control signal SWA matches the rising edge timing of the high potential of the control signal SWB. The falling edge timing of the high potential of the control SWB matches the rising edge timing of the high potential of the control signal SWC. The falling edge timing of the high potential of the control SWC matches the rising edge timing of the high potential of the control signal SWD. The falling edge timing of the high potential of the control SWD matches the falling edge timing of the high potential of the scanning signal G1.

As illustrated in FIGS. 10 and 11, while the high potential of the scanning signal G1 is supplied to the gate line 27, the image signals S0 to S2 are supplied to the source lines 28α to 28ζ in synchronization with the timing at which the control signals SWA to SWD rise up to have the high potential. With the first TFTs 24 that are connected to the gate line 27 being collectively driven, the image signals S0 to S2 supplied to the source lines 28α to 28ζ are supplied to the second source electrodes 25B of the second TFTs 25. At this time, some of the second TFTs 25 including the second gate electrodes 25A to which the control signals SWA to SWD having high potential are supplied are selectively driven. Accordingly, the pixel electrodes 26 that are connected to the selectively driven second TFTs 25 are charged to have the potential related to the image signals S0 to S2.

Specifically, as illustrated in FIGS. 10 and 11, while the control signal SWA has high potential, the image signal S1 for the first signal TFT 24α (the first pixel electrode 26α1) and the image signal S0 for the eighth signal TFT 24ι (the first pixel electrode 26α4) are supplied from the driver 12 to the first extending line 45α and the third extending line 45γ in synchronization with each other. While the control signal SWA has high potential, the control signals SWB to SWD have the potential of a low level (hereinafter, referred to as low potential). Therefore, while the control signal SWA has high potential, the first control TFT 25α and the eighth control TFT 25ι that are connected to the first control line 29α are driven; however, the second control TFT 25β and the fifth control TFT 25ζ connected to the second control line 29β, the third control TFT 25γ and the sixth control TFT 25η connected to the third control line 29γ, and the fourth control TFT 25δ and the seventh control TFT 25θ connected to the fourth control line 29δ are not driven. Therefore, the image signal S1 that is supplied from the driver 12 to the first source 28α and the second source line 28β via the first extending line 45α and the first short circuit line 44α is supplied to the first pixel electrode 26α1 via the first signal TFT 24α and the first control TFT 25α that are driven but not supplied to the second pixel electrode 26β1, the first pixel electrode 26α2, and the second pixel electrode 26β2 that are connected to the second control TFT 25β, the third control TFT 25γ, and the fourth control TFT 25δ that are not driven. On the other hand, the image signal S0 supplied from the driver 12 to the fifth source line 28ζ is supplied to the first pixel electrode 26α4 via the eighth signal TFT 24ι and the eighth control TFT 25ι that are driven. Accordingly, as illustrated in FIG. 12, the first pixel electrode 26α1 included in the first pixel column C1 is charged to have the positive potential related to the image signal S1 and the first pixel electrode 26α4 included in the second pixel column C2 is charged to have the negative potential related to the image signal S0.

As illustrated in FIGS. 10 and 11, while the control signal SWB has high potential, the image signal S1 for the second signal TFT 24β (the second pixel electrode 26β1) and the image signal S2 for the fifth signal TFT 24ζ (the second pixel electrode 26β3) are supplied from the driver 12 to the first extending line 45α and the second extending line 45β in synchronization with each other. While the control signal SWB has high potential, the control signals SWA, SWC, SWD have low potential. Therefore, while the control signal SWB has high potential, the second control TFT 25β and the fifth control TFT 25ζ that are connected to the second control line 29β are driven; however, the first control TFT 25α and the eighth control TFT 25ι that are connected to the first control line 29α, the third control TFT 25γ and the sixth control TFT 25η that are connected to the third control line 29γ, and the fourth control TFT 25δ and the seven control TFT 25θ that are connected to the fourth control line 29δ are not driven. Therefore, the image signal S1 that is supplied from the driver 12 to the first source line 28α and the second source line 28β via the first extending line 45α and the first short circuit line 44α is supplied to the second pixel electrode 26β1 via the second signal TFT 24β and the second control TFT 25β that are driven but not supplied to the first pixel electrode 26α1, the first pixel electrode 26α2, and the second pixel electrode 26β2 that are connected to the first control TFT 25α, the third control TFT 25γ, and the fourth control TFT 25δ that are not driven. On the other hand, the image signal S2 supplied from the driver 12 to the third source line 28γ and the fourth source line 28δ via the second extending line 45B and the second short circuit line 44B is supplied to the second pixel electrode 26β3 via the fifth signal TFT 24ζ and the fifth control TFT 25ζ that are driven but not supplied to the first pixel electrode 26α3 and the second pixel electrode 26β4 that are connected to the sixth control TFT 25η and the seventh control TFT 25θ that are not driven. Accordingly, as illustrated in FIG. 12, the second pixel electrode 26β1 included in the third pixel column C3 is charged to have the positive potential related to the image signal S1 and the second pixel electrode 26β3 included in the fourth pixel column C4 is charged to have the negative potential related to the image signal S2.

As illustrated in FIGS. 10 and 11, while the control signal SWC has high potential, the image signal S1 for the third signal TFT 24γ (the first pixel electrode 26α2) and the image signal S2 for the sixth signal TFT 24η (the first pixel electrode 26α3) are supplied from the driver 12 to the first extending line 45α and the second extending line 45β in synchronization with each other. While the control signal SWC has high potential, the control signals SWA, SWB, SWD have low potential. Therefore, while the control signal SWC has high potential, the third control TFT 25γ and the sixth control TFT 25η that are connected to the third control line 29γ are driven; however, the first control TFT 25α and the eighth control TFT 25ι that are connected to the first control line 29α, the second control TFT 25β and the fifth control TFT 25θ that are connected to the second control line 29β, and the fourth control TFT 25δ and the seventh control TFT 25θ that are connected to the fourth control line 29δ are not driven. Therefore, the image signal S1 that is supplied from the driver 12 to the first source line 28α and the second source line 28β via the first extending line 45α and the first short circuit line 44α is supplied to the first pixel electrode 26α2 via the third signal TFT 24γ and the third control TFT 25γ that are driven but not supplied to the first pixel electrode 26α1, the second pixel electrode 26β1, and the second pixel electrode 26β2 that are connected to the first control TFT 25α, the second control TFT 25β, and the fourth control TFT 25δ that are not driven. On the other hand, the image signal S2 supplied from the driver 12 to the third source line 28γ and the fourth source line 28δ via the second extending line 45β and the second short circuit line 44β is supplied to the first pixel electrode 26α3 via the sixth signal TFT 24η and the sixth control TFT 25η that are driven but not supplied to the second pixel electrode 26β3 and the second pixel electrode 26β4 that are connected to the fifth control TFT 25ζ and the seventh control TFT 25θ that are not driven. Accordingly, as illustrated in FIG. 12, the first pixel electrode 26α2 included in the fifth pixel column C5 is charged to have the positive potential related to the image signal S1 and the first pixel electrode 26α3 included in the sixth pixel column C6 is charged to have the negative potential related to the image signal S2.

As illustrated in FIGS. 10 and 11, while the control signal SWD has high potential, the image signal S1 for the fourth signal TFT 24δ (the second pixel electrode 26β2) and the image signal S2 for the seventh signal TFT 24θ (the second pixel electrode 26β3) are supplied from the driver 12 to the first extending line 45α and the second extending line 45β in synchronization with each other. While the control signal SWD has high potential, the control signals SWA, SWB, SWC have low potential. Therefore, while the control signal SWD has high potential, the fourth control TFT 25δ and the seventh control TFT 25θ that are connected to the fourth control line 29δ are driven; however, the first control TFT 25α and the eighth control TFT 25ι that are connected to the first control line 29α, the second control TFT 25β and the fifth control TFT 25ζ that are connected to the second control line 29β, and the third control TFT 25γ and the sixth control TFT 25η that are connected to the third control line 29γ are not driven. Therefore, the image signal S1 that is supplied from the driver 12 to the first source line 28α and the second source line 28β via the first extending line 45α and the first short circuit line 44α is supplied to the second pixel electrode 26β2 via the fourth signal TFT 24δ and the fourth control TFT 25δ that are driven but not supplied to the first pixel electrode 26α1, the second pixel electrode 26β1, and the first pixel electrode 26α2 that are connected to the first control TFT 25α, the second control TFT 25β, and the third control TFT 25γ that are not driven. On the other hand, the image signal S2 supplied from the driver 12 to the third source line 28γ and the fourth source line 28δ via the second extending line 45β and the second short circuit line 44β is supplied to the second pixel electrode 26β4 via the seventh signal TFT 240 and the seventh control TFT 25θ that are driven but not supplied to the second pixel electrode 26δ3 and the first pixel electrode 26α3 that are connected to the fifth control TFT 25θ and the sixth control TFT 25η that are not driven. Accordingly, as illustrated in FIG. 12, the second pixel electrode 26β2 included in the seventh pixel column C7 is charged to have the positive potential related to the image signal S1 and the second pixel electrode 26β4 included in the eighth pixel column C8 is charged to have the negative potential related to the image signal S2.

Thus, with the high potential being sequentially supplied to the gate lines 27 as the scanning signals G1, G2, G3 and the signals illustrated in FIG. 11 being outputted during a period while the scanning signal has high potential, as illustrated in FIG. 12, the first pixel electrode 26al included in the first pixel column C1, the second pixel electrode 26β1 included in the third pixel column C3, the first pixel electrode 26α2 included in the fifth pixel column C5, and the second pixel electrode 26β2 included in the seventh pixel column C7 are charged to have positive potential and the first pixel electrode 26α4 included in the second pixel column C2, the second pixel electrode 26β3 included in the fourth pixel column C4, the first pixel electrode 26α3 included in the sixth pixel column C6, and the second pixel electrode 26β4 included in the eighth pixel column C8 are charged to have negative potential. Accordingly, with the high potential being sequentially suppled to the gate lines 27 as the scanning signal, the pixel columns adjacent to each other in the X-axis direction have opposite polarities. Namely, the pixel columns having a same polarity are not arranged adjacent to each other and row inversion driving is performed. With the first connection line portion 26Bα of the first pixel electrode 26α crossing the source line 28 or the control line 29, the variation of arrangement of the first body portion 26Aα is increased and therefore, the row inversion driving can be performed. During a certain frame display period, the polarity of the image signals S0 to S2 does not change. For instance, with the polarity of the image signal S1 being positive during a period while the high potential is supplied as the scanning signal G1, the polarity of the image signal S1 is also positive during a period while the high potential is subsequently supplied as the scanning signal G2, G3. With the polarity of the image signals S0 and S2 being negative during a period while the high potential is supplied as the scanning signal G1, the polarity of the image signals S0 and S2 are also negative during a period while the high potential is subsequently supplied as the scanning signal G2, G3.

One frame display period after the output of the signals illustrated in FIG. 11, the signals illustrated in FIG. 13 are outputted. Among the signals illustrated in FIG. 13, the scanning signal G1 and the control signals SWA to SWD are same as those illustrated in FIG. 11; however, the image signals S0 to S2 have opposite polarities from those illustrated in FIG. 11. Specifically, the negative image signal S1 is supplied to the first source line 28α and the second source line 28β. The positive image signal S2 is supplied to the third source line 28γ and the fourth source line 28δ. The positive image signal S0 is supplied to the fifth source line 28.

With the signals illustrated in FIG. 13 being outputted, as illustrated in FIG. 14, the first pixel electrode 26α1 included in the first pixel column C1, the second pixel electrode 26β1 included in the third pixel column C3, the first pixel electrode 26α2 included in the fifth pixel column C5, and the second pixel electrode 26β2 included in the seventh pixel column C7 are charged to have negative potential and the first pixel electrode 26α4 included in the second pixel column C2, the second pixel electrode 26β3 included in the fourth pixel column C4, the first pixel electrode 26α3 included in the sixth pixel column C6, and the second pixel electrode 26β4 included in the eighth pixel column C8 are charged to have positive potential. Namely, the polarities of the pixel electrodes 26α1 to 26α4, 26β1 to 26β4 illustrated in FIG. 14 are opposite from those illustrated in FIG. 12.

As previously described, according to this embodiment, the signal supplied to the first source line 28α can be distributed to the first pixel electrode 26α1, which is a target pixel electrode 26 to be connected to the first control TFT 25α that is connected to the first control line 29α, and the second pixel electrode 26β1, which is a target pixel electrode 26 to be connected to the second control TFT 25B that is connected to the second control line 29β. The signal supplied to the second source line 28 can be distributed to the first pixel electrode 26α2, which is a target pixel electrode 26 to be connected to the third control TFT 25γ that is connected to the third control line 29γ, and the second pixel electrode 26β2, which is a target pixel electrode 26 to be connected to the fourth control TFT 25δ that is connected to the fourth control line 29δ. The signal supplied to the third source line 28γ can be distributed to the second pixel electrode 26β3, which is a target pixel electrode 26 to be connected to the fifth control TFT 25ζ that is connected to the second control line 29β, and the first pixel electrode 26α3, which is a target pixel electrode 26 to be connected to the sixth control TFT 25η that is connected to the third control line 29γ. With such a configuration, the number of source lines 28 is reduced.

While high potential is supplied to the gate line 27 as a scanning signal in a certain frame display period, the driver 12 supplies image signals having a same polarity (a positive polarity or a negative polarity) to the first source line 28α and the second source line 28β and supplies image signals having a same polarity (a negative polarity of a positive polarity) to the third source line 28γ and the fourth source line 28δ. Namely, in a certain frame display period, the polarity of the image signals supplied to the source lines 28 is not inverted. Therefore, power consumption necessary for supplying image signals from the driver 12 can be reduced compared to that necessary for supplying image signals having opposite polarities to the source lines from the driver every timing at which the control signal is supplied to each control line 29 from the control board 14.

As previously described, the liquid crystal display device 10 (the display device) of this embodiment includes the gate line 27 (the scan line) extending along the first direction, the source line 28 (the signal line) extending along the second direction that crosses the first direction and crossing the gate line 27, the control line 29 extending along the second direction and disposed spaced from the source line 28 and crossing the gate line 27, the pixel electrodes 26 arranged in a matrix in the first direction and the second direction, the first TFT 24 (the first switching component), and the second TFT 25 (the second switching component). The first TFT 24 includes the first gate electrode 24A (the first electrode) that is connected to one of the gate line 27 and the control line 29, the first source electrode 24B (the second electrode) that is connected to the source line 28, the first drain electrode 24C (the third electrode), and the first semiconductor section 24D that is connected to the first source electrode 24B and the first drain electrode 24C and overlaps the first gate electrode 24A. The second TFT 25 includes the second gate electrode 25A (the fourth electrode) that is connected to another one of the gate line 27 and the control line 29, the second source electrode 25B (the fifth electrode) that is connected to the first drain electrode 24C, the second drain electrode 25C (the sixth electrode) that is connected to the pixel electrode 26, and the second semiconductor section 25D that is connected to the second source electrode 25B and the second drain electrode 25C and overlaps the second gate electrode 25A. The pixel electrodes 26 includes the first pixel electrode 26α. The first pixel electrode 26α includes the first body portion 26Aα and the first connection line portion 26Bα that is connected to the first body portion 26Aα and the second drain electrode 25C. The first connection line portion 26Bα crosses the control line 29 or the source line 28.

With the gate line 27 being supplied with high potential, the first TFT 24 or the second TFT 25 that is connected to the gate line 27 is driven. With the control line 29 being supplied with high potential, the first TFT 24 or the second TFT 25 that is connected to the control line 29 is driven. With the source line 28 being supplied with a signal in synchronization with the timing at which the first TFT 24 is driven, the signal from the source line 28 is supplied from the first source electrode 24B to the first drain electrode 24C via the first semiconductor section 24D. With the second TFT 25 being driven in synchronization with the timing at which the first TFT 24 is driven, the signal from the first drain electrode 24C is supplied from the second source electrode 25B to the second drain electrode 25C via the second semiconductor section 25D. As a result, the pixel electrode 26 that is connected to the second drain electrode 25C is charged. The first pixel electrodes 26α included in the pixel electrodes 26 include the first body portions 26Aα and the first connection line portions 26Bα that are connected to the first body portions 26Aα and the second drain electrodes 25C. The first connection line portions 26Bα cross the source lines 28 or the control lines 29. Thus, with the first connection line portion 26Bα crossing the source line 28 or the control line 29, the variation of arrangement of the first body portion 26Aα of the first pixel electrode 26α is increased. With the variation of the arrangement of the first body portion 26Aα of the first pixel electrode 26α being increased and image signals whose polarity is not inverted in a certain frame display period but inverted in every frame display period being supplied to each source line 28, every two columns of the pixels having a same polarity are not arranged alternately. Therefore, display errors of stripes are less likely to be seen compared to the display device in which the arrangement of the pixel electrodes is fixed. Therefore, power consumption can be reduced with keeping display quality.

The first body portion 26Aα is disposed such that the first body portion 26Aα and the second TFT 25 that is connected to the first connection line portion 26Bα sandwich the control line 29 or the source line 28. The control line 29 or the source line 28 is disposed between the first body portion 26Aα and the second TFT 25 that is connected to the first connection line portion 26Bα. The first body portion 26Aα and the second TFT 25, which are arranged as described above, are connected by the first connection line portion 26Bα that crosses the control line 29 or the source line 28. Accordingly, the variation of arrangement of the first body portion 26Aα of the first pixel electrode 26α is increased.

The first gate electrode 24A is connected to the gate line 27 and the second gate electrode 25A is connected to the control line 29. With the gate line 27 being supplied with high potential, the first TFT 24 including the first gate electrode 24A that is connected to the gate line 27 is driven. With the control line 29 being supplied with high potential, the second TFT 25 including the second gate electrode 25A that is connected to the control line 29 is driven.

The second TFT 25 is closer to the control line 29 than the source line 28. The distance between the second gate electrode 25A of the second TFT 25 and the control line 29 that is connected to the second gate electrode 25A can be shorter compared to a configuration in which the second TFT is closer to the source line than the control line. With such a configuration, delay due to parasitic capacitance and electric resistance is less likely to be caused in signals that are supplied to the second gate electrode 25A from the control line 29.

The first TFT 24 is closer to the source line 28 than the control line 29. The distance between the first source electrode 24B of the first TFT 24 and the source line 28 that is connected to the first source electrode 24B can be shorter compared to a configuration in which the first TFT is closer to the control line than the source line. With such a configuration, delay due to parasitic capacitance and electric resistance is less likely to be caused in signals that are supplied to the first source electrode 24B from the source line 28.

The control lines 29 are arranged at intervals in the first direction and include the first control line 29α and the second control line 29β. The source lines 28 are arranged at intervals in the first direction and include the first source line 28α (the first signal line). The second TFTs 25 are arranged at intervals in the first direction. One of the second TFTs 25 is defined as the first control TFT 25α (the first control switching component) that includes the second gate electrode 25A connected to the first control line 29α and another one of the second TFTs 25 is defined as the second control TFT 25β (the second control switching component) that includes the second gate electrode 25A connected to the second control line 29β. The first TFTs 24 are arranged at intervals in the first direction. One of the first TFTs 24 is defined as the first signal TFT 24α (the first signal switching component) and another one of the first TFTs 24 is defined as the second signal TFT 24β (the second signal switching component). The first signal TFT 24α includes the first source electrode 24B that is connected to the first source line 28α and the first drain electrode 24C that is connected to the second source electrode 25B of the first control TFT 25α. The second signal TFT 24β includes the first source electrode 24B that is connected to the first source line 28α and the first drain electrode 24C that is connected to the second source electrode 25B of the second control TFT 25β. While the gate line 27 is supplied with high potential, a signal is supplied to the first source line 28α in synchronization with the timing at which the first control line 29α is supplied with high potential. Then, the first control TFT 25α connected to the first control line 29α and the first signal TFT 24α connected to the first control TFT 25α are driven and the signal supplied to the first source line 28α is supplied to the pixel electrode 26 that is a target to be connected to the first control TFT 25α. On the other hand, while the gate line 27 is supplied with high potential, a signal is supplied to the first source line 28α in synchronization with the timing at which the second control line 29β is supplied with high potential. Then, the second control TFT 25B connected to the second control line 29β and the second signal TFT 24β connected to the second control TFT 25β are driven and the signal supplied to the first source line 28α is supplied to the pixel electrode 26 that is a target to be connected to the second control TFT 25β. Accordingly, the signal supplied to the first source line 28α can be distributed to the target pixel electrode 26 to be connected to the first control TFT 25α that is connected to the first control line 29α and the target pixel electrode 26 to be connected to the second control TFT 25β that is connected to the second control line 29β.

The liquid crystal display device 10 of this embodiment further includes the control board 14 (the first signal supply section) that is connected to the control lines 29 and supplies signals to the control lines 29. The control board 14 is configured to supply high-level potential to the first control line 29α and the second control line 29β at different timings. With high potential being supplied to the first control line 29α and the second control line 29β at different timings from the control board 14, the signal supplied to the source line 28 can be distributed to the target pixel electrode 26 to be connected to the first control TFT 25α that is connected to the first control line 29α and the target pixel electrode 26 to be connected to the second control TFT 25β that is connected to the second control line 29β.

The control lines 29 include the third control line 29γ and the fourth control line 298. The source lines 28 include the second source line 28β (the second signal line). One of the second TFTs 25 is defined as the third control TFT 25γ (the third control switching component) that includes the second gate electrode 25A connected to the third control line 29γ and another one of the second TFTs 25 is defined as the fourth control TFT 25δ (the fourth control switching component) that includes the second gate electrode 25A connected to the fourth control line 29δ. One of the first TFTs 24 is defined as the third signal TFT 24γ (the third signal switching component) and another one of the first TFTs 24 is defined as the fourth signal TFT 24δ (the fourth signal switching component). The third signal TFT 24γ includes the first source electrode 24B that is connected to the second source line 28β and the first drain electrode 24C that is connected to the second source electrode 25B of the third control TFT 25γ. The fourth signal TFT 24δ includes the first source electrode 24B that is connected to the second source line 28β and the first drain electrode 24C that is connected to the second source electrode 25B of the fourth control TFT 25δ. While the gate line 27 is supplied with high potential, a signal is supplied to the second source line 28β in synchronization with the timing at which the third control line 29γ is supplied with high potential. Then, the third control TFT 25γ connected to the third control line 29γ and the third signal TFT 24γ connected to the third control TFT 25γ are driven and the signal supplied to the second source line 28β is supplied to the target pixel electrode 26 that is to be connected to the third control TFT 25γ. On the other hand, while the gate line 27 is supplied with high potential, a signal is supplied to the second source line 28β in synchronization with the timing at which the fourth control line 29δ is supplied with high potential. Then, the fourth control TFT 25δ connected to the fourth control line 29δ and the fourth signal TFT 24δ connected to the fourth control TFT 25δ are driven and the signal supplied to the second source line 28β is supplied to the target pixel electrode 26 that is to be connected to the fourth control TFT 25δ. Accordingly, the signal supplied to the first source line 28α can be distributed to the target pixel electrode 26 to be connected to the first control TFT 25α that is connected to the first control line 29α and the target pixel electrode 26 to be connected to the second control TFT 25β that is connected to the second control line 29β. Furthermore, the signal supplied to the second source line 28β can be distributed to the target pixel electrode 26 to be connected to the third control TFT 25γ that is connected to the third control line 29γ and the target pixel electrode 26 to be connected to the fourth control TFT 25δ that is connected to the fourth control line 298.

The liquid crystal display device 10 further includes the first short circuit line 44α, the first extending line 45α, and the driver 12 (the second signal supply section). The first short circuit line 44α extends along the first direction and is connected to the first source line 28α and the second source line 28β to cause a short circuit between the first source line 28α and the second source line 28B. The first extending line 45α is connected to one of the first source line 28α, the second source line 28B, and the first short circuit line 44α. The driver 12 is connected to the first extending line 45α and supplies signals to the first extending line 45α. Thus, with the signals being supplied to the first extending line 45α from the driver 12, the signals are supplied to the first source line 28α and the second source line 28β that are connected by the first short circuit line 44α. With only one first extending line 45α being connected to the driver 12, the frame width can be preferably reduced compared to a configuration in which each of the first source line 28α and the second source line 28β is connected to the driver 12 without including the first short circuit line 44α.

The liquid crystal display device 10 further includes the control board 14 that is connected to the control lines 29 for supplying signals to each of the control lines 29. The control board 14 is configured to supply high-level potential to the first control line 29α, the second control line 29β, the third control line 29γ, and the fourth control line 29δ at different timings. The driver 12 is configured to supply a signal to the first signal TFT 24α in synchronization with the timing at which the first control line 29α is supplied with high-level potential, to supply a signal to the second signal TFT 24β in synchronization with the timing at which the second control line 29β is supplied with high-level potential, to supply a signal to the third signal TFT 24γ in synchronization with the timing at which the third control line 29γ is supplied with high-level potential, and to supply a signal to the fourth signal TFT 24δ in synchronization with the timing at which the fourth control line 29δ is supplied with high-level potential. With a signal being supplied to the first extending line 45α from the driver 12 in synchronization with the timing at high potential is supplied to the first control line 29α from the control board 14, the first signal TFT 24α and the first control TFT 25α are driven and the signal is supplied to the target pixel electrode 26 that is to be connected to the first control TFT 25α. With a signal being supplied to the first extending line 45α from the driver 12 in synchronization with the timing at high potential is supplied to the second control line 29β from the control board 14, the second signal TFT 24β and the second control TFT 25β are driven and the signal is supplied to the target pixel electrode 26 that is to be connected to the second control TFT 25β. With a signal being supplied to the first extending line 45α from the driver 12 in synchronization with the timing at high potential is supplied to the third control line 29γ from the control board, the third signal TFT 24γ and the third control TFT 25γ are driven and the signal is supplied to the target pixel electrode 26 that is to be connected to the third control TFT 25γ. With a signal being supplied to the first extending line 45α from the driver 12 in synchronization with the timing at high potential is supplied to the fourth control line 29δ from the control board 14, the fourth signal TFT 24δ and the fourth control TFT 25δ are driven and the signal is supplied to the target pixel electrode 26 that is to be connected to the fourth control TFT 25δ.

The first source line 28α is disposed between the first control line 29α and the second control line 29β with respect to the first direction and the second source line 28 is disposed between the third control line 29γ and the fourth control line 29δ with respect to the first direction. The source lines 28 include the third source line 28γ (the third signal line) that is disposed between the second control line 29 and the third control line 29γ with respect to the first direction. One of the first TFTs 24 is defined as the fifth TFT 24ζ (the fifth signal switching component) that includes the first source electrode 24B connected to the third source line 28γ and another one of first TFTs 24 is defined as the sixth TFT 24η (the sixth signal switching component) that includes the first source electrode 24B connected to the third source line 28γ. The third source line 28γ is sandwiched between the fifth signal TFT 24ζ and the sixth signal TFT 24η. One of the second TFTs 25 is defined as the fifth control TFT 25ζ (the fifth control switching component) that includes the second source electrode 25B connected to the first drain electrode 24C of the fifth signal TFT 24ζ and another one of the second TFTs 25 is defined as the sixth control TFT 25η (the sixth control switching component) that includes the second source electrode 25B connected to the first drain electrode 24C of the sixth signal TFT 24η. The second gate electrode 25A of the fifth control TFT 25ζ is connected to the second control line 29β and the second gate electrode 25A of the sixth control TFT 25η is connected to the third control line 29γ. While the gate line 27 is supplied with high potential, a signal is supplied to the third source line 28γ in synchronization with the timing at which the second control line 29β is supplied with high potential. Then, the fifth control TFT 25ζ that is connected to the second control line 29B and the fifth signal TFT 24ζ that is connected to the fifth control TFT 25ζ are driven and the signal supplied to the third source line 28γ is supplied to the target pixel electrode 26 that is to be connected to the fifth control TFT 255. On the other hand, while the gate line 27 is supplied with high potential, a signal is supplied to the third source line 28γ in synchronization with the timing at which the third control line 29γ is supplied with high potential. Then, the sixth control TFT 25η that is connected to the third control line 29γ and the sixth signal TFT 24η that is connected to the sixth control TFT 25η are driven and the signal supplied to the third source line 28γ is supplied to the target pixel electrode 26 that is to be connected to the sixth control TFT 25η.

The source lines 28 include the fourth source line 28δ (the fourth signal line) that is disposed such that the fourth control line 29δ is sandwiched between the fourth source line 28δ and the second source line 28β with respect to the first direction. One of the first TFTs 24 that includes the first source electrode 24B connected to the fourth source line 28δ is defined as the seventh signal TFT 24θ (the seventh signal switching component). One of the second TFTs 25 that includes the second source electrode 25B connected to the first drain electrode 24C of the seventh signal TFT 24θ is defined as the seventh control TFT 25θ (the seventh control switching component). The second gate electrode 25A of the seventh control TFT 25θ is connected to the fourth control line 29δ. while the gate line 27 is supplied with high potential, a signal is supplied to the fourth source line 28δ in synchronization with the timing at which the fourth control line 29δ is supplied with high potential. Then, the seventh control TFT 25θ that is connected to the fourth control line 29θ and the seventh signal TFT 24θ that is connected to the seventh control TFT 25θ are driven and the signal supplied to the fourth source line 28δ is supplied to the target pixel electrode 26 that is to be connected to the seventh control TFT 25θ.

The pixel electrodes 26 include the first pixel electrodes 26α and the second pixel electrodes 26β. The second pixel electrode 26β includes the second body portion 26Aβ and the second connection line portion 26Bβ that is connected to the second body portion 26Aβ and the second drain electrode 25C and does not cross the control line 29 and the source line 28. The first pixel electrodes 26α include the first pixel electrode 26α1, first pixel electrode 26α2, and first pixel electrode 26α3. The first body portion 26Aα of the first pixel electrode 26α1 is on an opposite side from the first source line 28α with respect to the first control line 29α in the first direction and the first connection line portion 26Bα of the first pixel electrode 26α1 is connected to the second drain electrode 25C of the first control TFT 25α and crosses the first control line 29α. The first body portion 26Aα of the first pixel electrode 26α2 is disposed between the third source line 28γ and the third control line 29γ in the first direction and the first connection line portion 26Bα of the first pixel electrode 26α2 is connected to the second drain electrode 25C of the third control TFT 25γ and crosses the third control line 29γ. The first body portion 26Aα of the first pixel electrode 26α3 is disposed between the third control line 29γ and the second source line 28 in the first direction and the first connection line portion 26Bα of the first pixel electrode 26α3 is connected to the second drain electrode 25C of the sixth control TFT 25η and crosses the third control line 29γ. The second pixel electrodes 26β include the second pixel electrode 2631, the second pixel electrode 26β2, and the second pixel electrode 26β3. The second body portion 26Aβ of the second pixel electrode 26β1 is disposed between the first source line 28α and the second control line 29β in the first direction and the second connection line portion 26Bβ of the second pixel electrode 26β1 is connected to the second drain electrode 25C of the second control TFT 25β. The second body portion 26Aβ of the second pixel electrode 26β2 is disposed between the second source line 28 and the fourth control line 29δ in the first direction and the second connection line portion 26Bβ of the second pixel electrode 26β2 is connected to the second drain electrode 25C of the fourth control TFT 25δ. The second body portion 26Aβ of the second pixel electrode 26β3 is disposed between the second control line 29 and the third source line 28γ in the first direction and the second connection line portion 26Bβ of the second pixel electrode 26β3 is connected to the second drain electrode 25C of the fifth control TFT 25ζ A signal supplied to the first source line 28α is supplied to the first pixel electrode 26α1 that is connected to the first control TFT 25α at the timing when high potential is supplied to the first control line 29α and is supplied to the second pixel electrode 26β1 that is connected to the second control TFT 25β at the timing when high potential is supplied to the second control line 29β. A signal supplied to the second source line 28β is supplied to the first pixel electrode 26α2 that is connected to the third control TFT 25γ at the timing when high potential is supplied to the third control line 29γ and is supplied to the second pixel electrode 26β2 that is connected to the fourth control TFT 25δ at the timing when high potential is supplied to the fourth control line 29δ. A signal supplied to the third source line 28γ is supplied to the second pixel electrode 26β3 that is connected to the fifth control TFT 25ζ at the timing when high potential is supplied to the second control line 29 and is supplied to the first pixel electrode 26α3 that is connected to the sixth control TFT 25η at the timing when high potential is supplied to the third control line 29γ.

The first body portion 26Aα and the second body portion 26Aβ have substantially a same area and the first connection line portion 26Bα and the second connection line portion 26Bβ have substantially a same area. Accordingly, the first pixel electrode 26α and the second pixel electrode 26β have substantially a same area. Therefore, display unevenness is less likely to be caused.

The length of the first connection line portion 26Bα extending from the first body portion 26Aα to the second drain electrode 25C is substantially same as the length of the second connection line portion 26Bβ extending from the second body portion 26Aβ to the second drain electrode 25C. With such a configuration including the same lengths of the first connection line portion 26Bα and the second connection line portion 26Bβ, even if the widths of the first connection line portion 26Bα and the second connection line portion 26Bβ are varied due to the manufacturing reasons, difference in the areas of the first connection line portion 26Bα and the second connection line portion 26Bβ is less likely to be caused. Accordingly, display unevenness is less likely to be caused.

The liquid crystal display device 10 further includes the driver 12 that is connected to the source lines 28 and supplies signals to the source lines 28. The signals supplied to the first source line 28α and the second source line 28β from the driver 12 and the signals supplied to the third source line 28γ from the driver 12 have opposite polarities. With the first pixel electrodes 26α being connected to the first control TFT 25α, the third control TFT 25γ, and the sixth control TFT 25η, respectively, and the second pixel electrodes 26β being connected to the second control TFT 25β, the fourth control TFT 25δ, and the fifth control TFT 25ζ, respectively, and the signals supplied to the first source line 28α and the second source line 28β and the signals supplied to the third source line 28γ having opposite polarities, the pixel electrodes 26 that are adjacent to each other in the first direction are charged to have potentials having opposite polarities. Specifically, the second pixel electrode 26β that is connected to the second control TFT 25β and the second pixel electrode 26 that is connected to the fifth control TFT 25ζ have opposite polarities. The second pixel electrode 26β that is connected to the fifth control TFT 25ζ and the first pixel electrode 26α that is connected to the third control TFT 25γ have opposite polarities. The first pixel electrode 26α that is connected to the third control TFT 25γ and the first pixel electrode 26α that is connected to the sixth control TFT 25η have opposite polarities. The first pixel electrode 26α that is connected to the sixth control TFT 25η and the second pixel electrode 26β that is connected to the fourth control TFT 25δ have opposite polarities. Accordingly, display errors of stripes are less likely to be seen.

The driver 12 supplies signals having a same polarity to the first source line 28α, the second source line 28β, and the third source line 28γ in synchronization with the supply of high-level potential to the first control line 29, the second control line 29β, the third control line 29γ, and the fourth control line 29δ from the control board 14. Accordingly, the power consumption required for supplying signals is reduced compared to a configuration in which the polarity of the image signals supplied to the source lines from the driver is inverted every time high potential is supplied to the control lines 29 from the control board 14.

### Second Embodiment

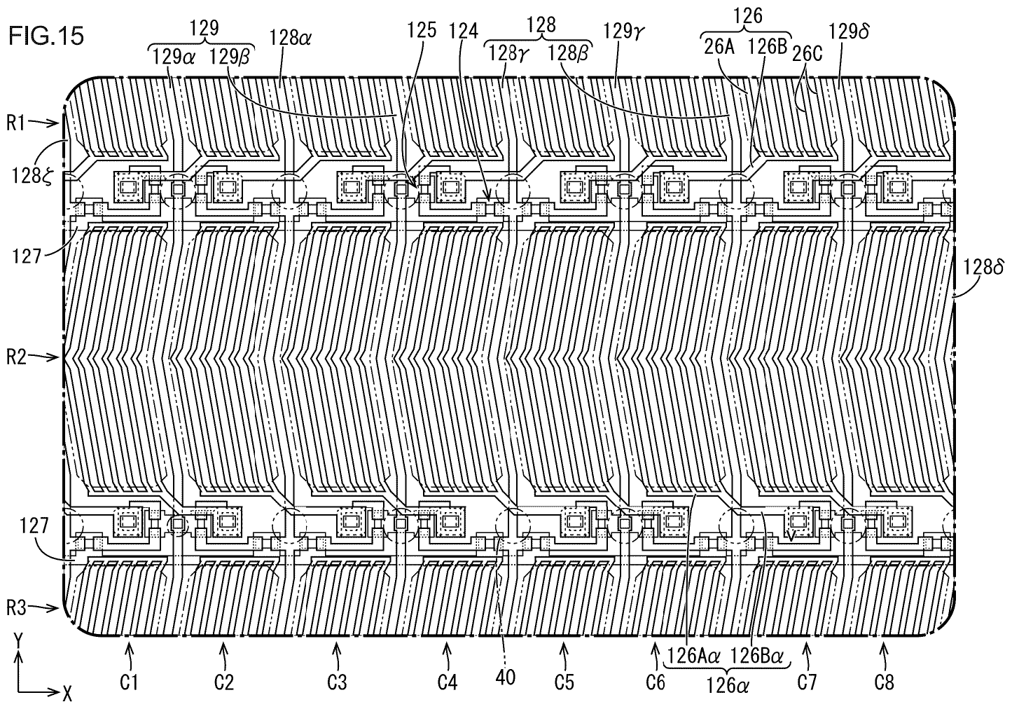

A second embodiment will be described with reference to FIGS. 15 to 23. The second embodiment includes a connection line portion 126β having a configuration different from that of the first embodiment. Configuration, operations, and effects similar to those of the first embodiment may not be described.

As illustrated in FIG. 15, pixel electrodes 126 of this embodiment are first pixel electrodes 126α and do not include the second pixel electrode 26β of the first embodiment (refer to FIG. 3). Namely, the first connection line portions 126β of the pixel electrodes 126 are first connection line portions 126Bα and cross a source line 128 or a control line 129. Detailed arrangement and a configuration of first body portions 126Aα and the first connection line portions 126Bα will be described later.

One of the first pixel electrodes 126α that is connected to a first control TFT 125α is defined as a first pixel electrode 126α5. One of the first pixel electrodes 126α that is connected to a second control TFT 125β is defined as a first pixel electrode 126α6. One of the first pixel electrodes 126α that is connected to a third control TFT 125γ is defined as a first pixel electrode 26α7. One of the first pixel electrodes 126α that is connected to a fourth control TFT 125δ is defined as a first pixel electrode 26α8. One of the first pixel electrodes 126α that is connected to a fifth control TFT 125ζ is defined as a first pixel electrode 126α9. One of the first pixel electrodes 126α that is connected to a sixth control TFT 125η is defined as a first pixel electrode 26α10. One of the first pixel electrodes 126α that is connected to a seventh control TFT 25θ is defined as a first pixel electrode 126α11. One of the first pixel electrodes 126α that is connected to an eighth control TFT 125ι is defined as a first pixel electrode 26α12.

In this embodiment, as illustrated in FIG. 15, the arrangement of the first body portions 126Aα of the first pixel electrodes 126α is varied in every pixel row. Specifically, among the pixel rows that are arranged in the Y-axis direction, in the odd-numbered pixel rows from the upper edge in FIG. 15 (for instance, a first pixel row R1 and a third pixel row R3 that are a first one and a third one from the upper edge in FIG. 15), the first body portion 126Aα of the first pixel electrode 126α12 is included in the second pixel column C2, the first body portion 126Aα of the first pixel electrode 126α5 is included in the third pixel column C3, the first body portion 126Aα of a first pixel electrode 126α6 is included in the fourth pixel column C4, the first body portion 126Aα of a first pixel electrode 126α9 is included in the fifth pixel column C5, the first body portion 126Aα of a first pixel electrode 126α10 is included in the sixth pixel column C6, the first body portion 126Aα of a first pixel electrode 126α7 is included in the seventh pixel column C7, and the first body portion 126Aα of a first pixel electrode 126α8 is included in the eighth pixel column C8. Thus, in the odd-numbered pixel rows, the first body portions 126Aα to be connected are disposed on the right side of the second TFTs 125.

In the even-numbered pixel rows from the upper edge in FIG. 15 (for instance, a second pixel row R2 that is a second one from the upper edge in FIG. 15), the first body portion 126Aα of the first pixel electrode 126α5 is included in the first pixel column C1, the first body portion 126Aα of the first pixel electrode 126α6 is included in the second pixel column C2, the first body portion 126Aα of the first pixel electrode 126α9 is included in the third pixel column C3, the first body portion 126Aα of the first pixel electrode 126α10 is included in the fourth pixel column C4, the first body portion 126Aα of the first pixel electrode 126α7 is included in the fifth pixel column C5, the first body portion 126Aα of the first pixel electrode 126α8 is included in the sixth pixel column C6, and the first body portion 126Aα of a first pixel electrode 126α11 is included in the seventh pixel column C7. Thus, in the even-numbered pixel rows, the first body portions 126Aα to be connected are disposed on the left side of the second TFTs 125.

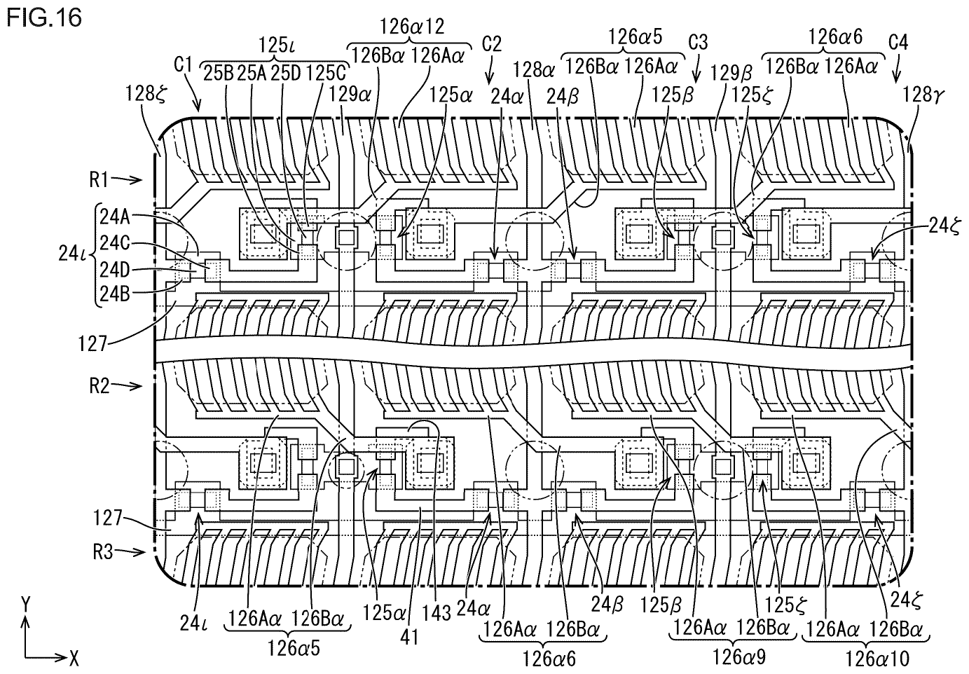

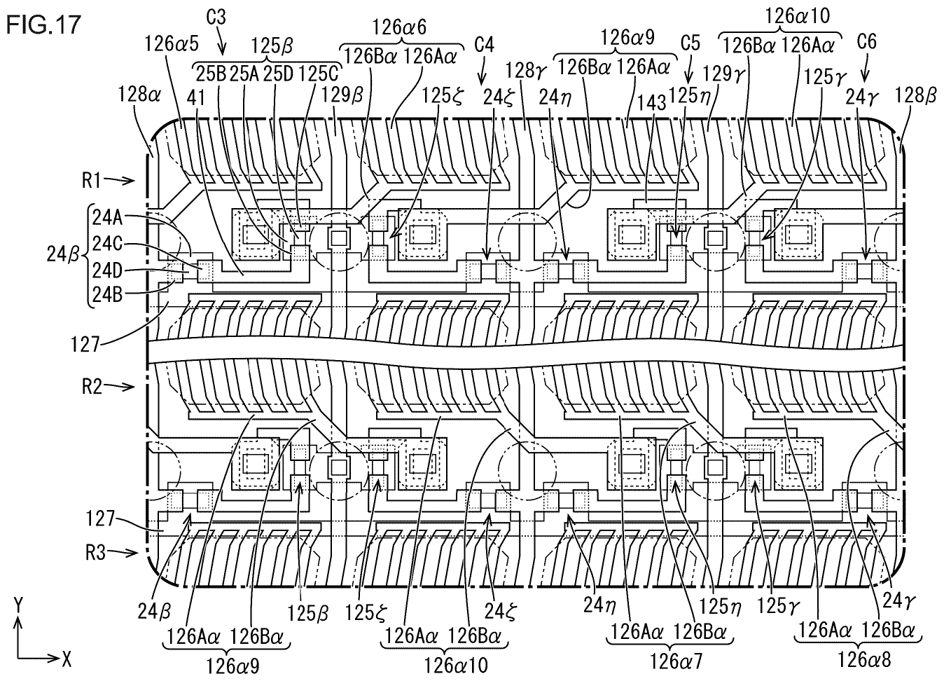

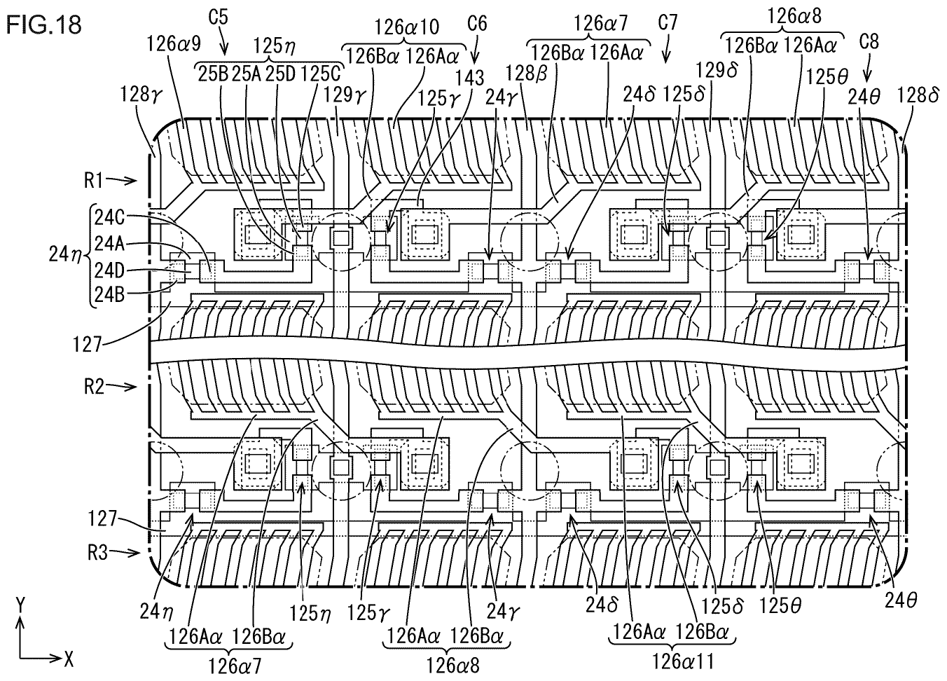

As illustrated in FIGS. 16 to 18, the first connection line portions 126Bα of the first pixel electrodes 126α cross different lines 128, 129 in each pixel row such that the first body portions 126Aα are arranged as described above. FIG. 16 is a plan view illustrating the first pixel column C1 to the fourth pixel column C4. FIG. 17 is a plan view illustrating the third pixel column C3 to the sixth pixel column C6. FIG. 18 is a plan view illustrating the fifth pixel column C5 to the eighth pixel column C8. In the following, the first pixel row R1 will be described as an example of the odd-numbered pixel rows and the second pixel row R2 will be described as an example of the even-numbered pixel rows.

As illustrated in FIG. 16, in the first pixel row R1, the first connection line portion 126Bα of the first pixel electrode 126α12 extends from a drain line section 143 (a second drain electrode 125C) of the eighth control TFT 125ι to the first body portion 126Aα, which is a target to be connected, with crossing the first control line 129α. In the first pixel row R1, the first connection line portion 126Bα of the first pixel electrode 126α5 extends from the drain line section 143 of the first control TFT 125α to the first body portion 126Aα, which is a target to be connected, with crossing the first source line 128α. In the first pixel row R1, the first connection line portion 126Bα of the first pixel electrode 126α6 extends from the drain line section 143 of the second control TFT 125β to the first body portion 126Aα, which is a target to be connected, with crossing the second control line 129B. In the first pixel row R1, as illustrated in FIG. 17, the first connection line portion 126Bα of the first pixel electrode 126α9 extends from the drain line section 143 of the fifth control TFT 125ζ to the first body portion 126Aα, which is a target to be connected, with crossing the third source line 128γ. In the first pixel row R1, the first connection line portion 126Bα of the first pixel electrode 126α10 extends from the drain line section 143 of the sixth control TFT 125η to the first body portion 126Aα, which is a target to be connected, with crossing the third control line 129γ. In the first pixel row R1, as illustrated in FIG. 18, the first connection line portion 126Bα of the first pixel electrode 126α7 extends from the drain line section 143 of the third control TFT 125γ to the first body portion 126Aα, which is a target to be connected, with crossing the second source line 128B. In the first pixel row R1, the first connection line portion 126Bα of the first pixel electrode 126α8 extends from the drain line section 143 of the fourth control TFT 125δ to the first body portion 126Aα, which is a target to be connected, with crossing the fourth control line 1298. Thus, in the first pixel row R1, all the first connection line portions 126Bα extend rightward from the drain line section 143 as illustrated in FIGS. 15 to 18.

As illustrated in FIG. 16, in the second pixel row R2, the first connection line portion 126Bα of the first pixel electrode 126α5 extends from the drain line section 143 of the first control TFT 125α to the first body portion 126Aα, which is a target to be connected, with crossing the first control line 129α. In the second pixel row R2, the first connection line portion 126Bα of the first pixel electrode 126α6 extends from the drain line section 143 of the second control TFT 125β to the first body portion 126Aα, which is a target to be connected, with crossing the first source line 128α. In the second pixel row R2, the first connection line portion 126Bα of the first pixel electrode 126α9 extends from the drain line section 143 of the fifth control TFT 125ζ to the first body portion 126Aα, which is a target to be connected, with crossing the second control line 129B. In the second pixel row R2, as illustrated in FIG. 17, the first connection line portion 126Bα of the first pixel electrode 126α10 extends from the drain line section 143 of the sixth control TFT 125η to the first body portion 126Aα, which is a target to be connected, with crossing the third source line 128γ. In the second pixel row R2, the first connection line portion 126Bα of the first pixel electrode 126α7 extends from the drain line section 143 of the third control TFT 125γ to the first body portion 126Aα, which is a target to be connected, with crossing the third control line 129γ. In the second pixel row R2, as illustrated in FIG. 18, the first connection line portion 126Bα of the first pixel electrode 126α8 extends from the drain line section 143 of the fourth control TFT 125δ to the first body portion 126Aα, which is a target to be connected, with crossing the second source line 128β. In the second pixel row R2, the first connection line portion 126Bα of the first pixel electrode 126α11 extends from the drain line section 143 of the seventh control TFT 1250 to the first body portion 126Aα, which is a target to be connected, with crossing the fourth control line 129δ. Thus, in the second pixel row R2, all the first connection line portions 126Bα extend leftward from the drain line section 143 as illustrated in FIGS. 15 to 18.

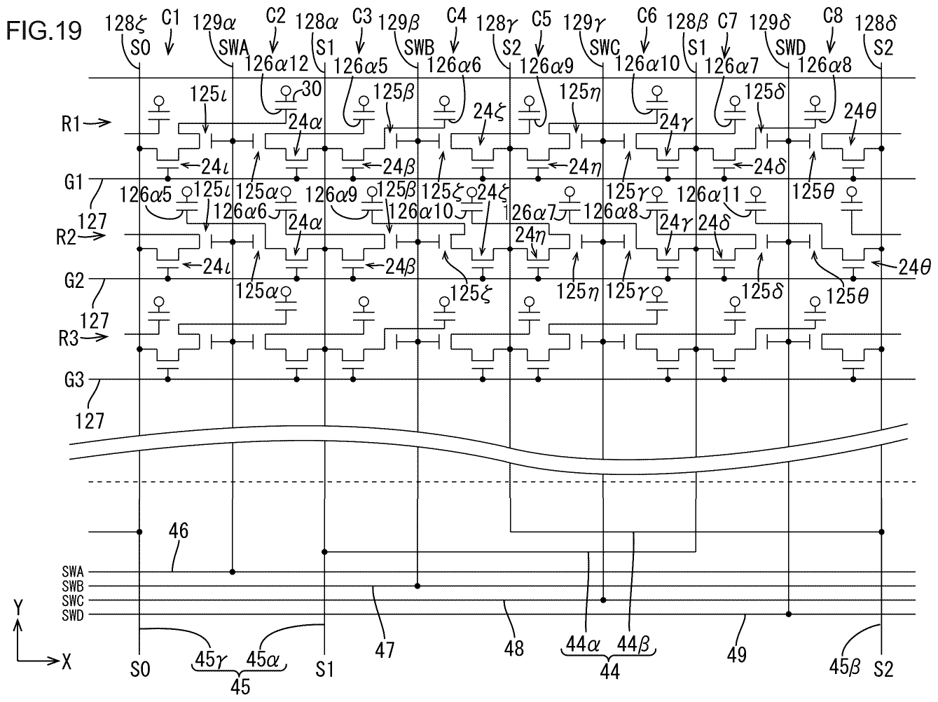

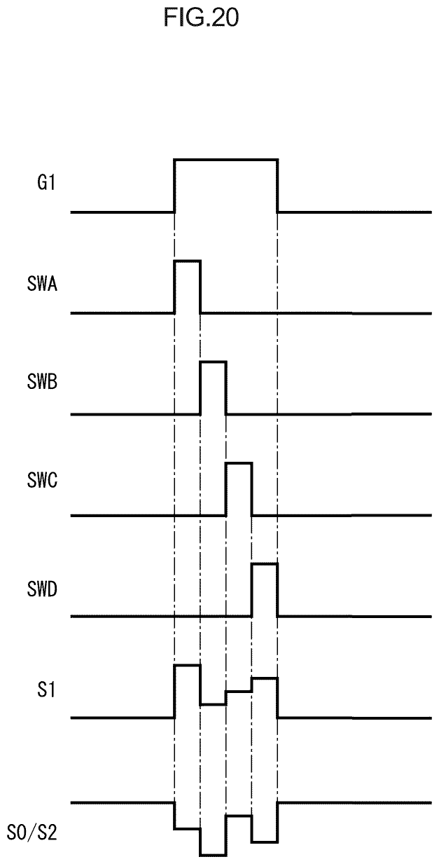

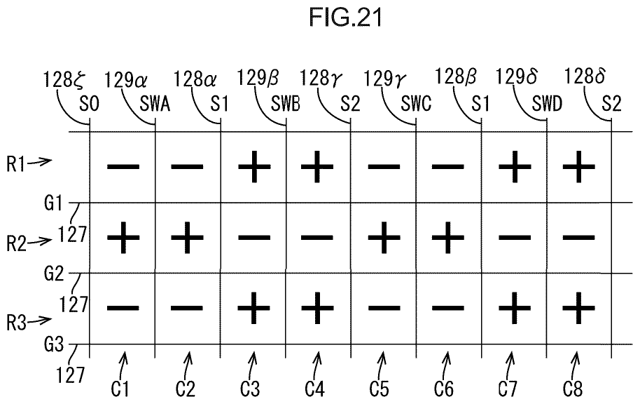

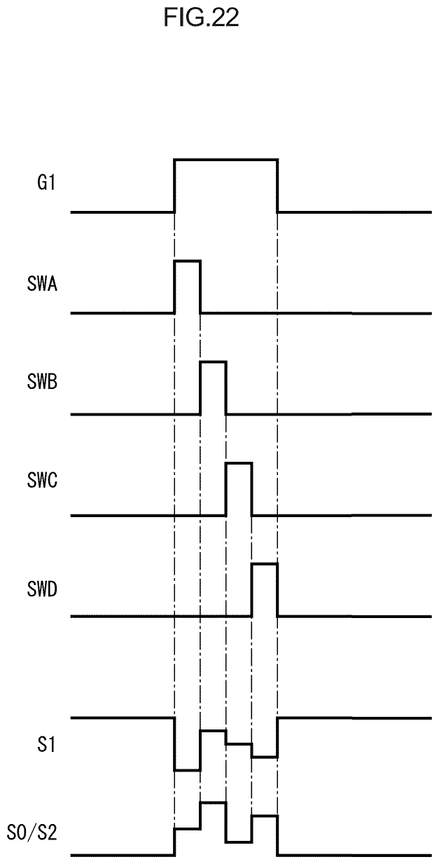

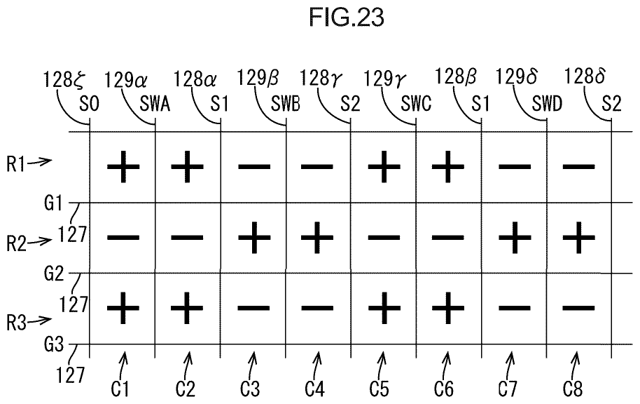

The present embodiment has the configuration described above and operations will be described with reference to FIGS. 19 to 23. FIGS. 20 and 22 illustrates waveforms of signals transmitted through gate lines 127, the source lines 128α to 128ζ, and the control lines 129α to 129δ. FIG. 22 illustrates waveforms of signals outputted after one frame display period after the output of the signals illustrated in FIG. 20. In FIGS. 20 and 22, similar to FIGS. 11 and 13, the scanning signal G1, the control signals SWA to SWD, and the image signals S0 to S2 are illustrated. In FIGS. 21 and 23, the first pixel electrodes 126α5 to 126α12, the gate lines 127, the source lines 128α to 128ζ, and the control lines 129α to 129δ are typically illustrated and the positive polarity and the negative polarity of each of the first pixel electrodes 126α5 to 126α12 are illustrated with the symbols of “+” and

As illustrated in FIGS. 19 and 20, in synchronization with the supply of high potential of the scanning signal G1, G2 to the gate line 127 from the gate driver circuit 15, the high potential of the control signals SWA to SWD are supplied to the control lines 129α to 129δ from the control board 14 at different timings and the image signals S0 to S2 are supplied to the source lines 128α to 128ζ from the driver 12 in synchronization with the timing at which the control signals SWA to SWD are supplied to the control lines 129α to 129δ. Relation of the timing at which high potential is supplied as the scanning signal G1, G2 and the timing at which high potential is supplied as the control signal SWA to SWD is same as that described in the first embodiment. Relation of the timing at which high potential is supplied as the control signal SWA to SWD and the timing at which the image signal S0 to S2 is supplied is same as that described in the first embodiment. The polarities of the image signals S0 to S2 are same as those described in the first embodiment. The polarity of the image signal S1 is opposite from the polarity of the image signals S0, S2.

Specifically, as illustrated in FIGS. 19 and 20, with high potential of the scanning signal G1 being supplied to the gate line 127 that is connected to the first TFTs 124 included in the first pixel row R1, the first TFTs 124 connected to the gate line 127 are collectively driven. While high potential of the scanning signal G1 is supplied to the gate line 127, high potential of the control signals SWA to SWD is supplied to the first control line 129α, the second control line 129β, the third control line 129γ, and the fourth control line 129δ in this order. While high potential of the scanning signal G1 is supplied to the gate line 127, the image signals S0 to S2 are supplied to the source lines 128α to 128ζ in synchronization with the timing at which the control signals SWA to SWD rise up to have the high potential. The operation of the control TFTs 125α to 125ι is same as that described in the first embodiment. In FIG. 20, the image signal S1 of a positive polarity and the image signals S0, S2 of a negative polarity are supplied to the source lines 128α to 128ζ.

With the TFTs 124, 125 being driven based on the scanning signals G1 and the control signals SWA to SWD, the first pixel electrodes 126α included in the first pixel row R1 are charged to have the polarities illustrated in FIG. 21. Namely, the first pixel electrode 126α12 included in the second pixel column C2 is charged to have the negative potential related to the image signal S0, the first pixel electrode 126α5 included in the third pixel column C3 is charged to have the positive potential related to the image signal S1, the first pixel electrode 126α6 included in the fourth pixel column C4 is charged to have the positive potential related to the image signal S1, the first pixel electrode 126α9 included in the fifth pixel column C5 is charged to have the negative potential related to the image signal S2, the first pixel electrode 126α10 included in the sixth pixel column C6 is charged to have the negative potential related to the image signal S2, the first pixel electrode 126α7 included in the seventh pixel column C7 is charged to have the positive potential related to the image signal S1, and the first pixel electrode 126α8 included in the eighth pixel column C8 is charged to have the positive potential related to the image signal S1. Thus, in the first pixel row R1, every two of the first pixel electrodes 126α that are adjacent to each other in the X-axis direction have the potential of a same polarity. Specifically, in the first pixel row R1, the (4n−3)th pixel column and the (4n−2)th pixel column from the left end in FIG. 21 have negative potential and the (4n−1)th pixel column and the 4nth pixel column have positive potential (n: natural number).

With the TFTs 124, 125 being driven based on the scanning signals G1 and the control signals SWA to SWD, the first pixel electrodes 126α included in the second pixel row R2 are charged to have the polarities illustrated in FIG. 21. Namely, the first pixel electrode 126α5 included in the first pixel column C1 is charged to have the positive potential related to the image signal S1, the first pixel electrode 126α6 included in the second pixel column C2 is charged to have the positive potential related to the image signal S1, the first pixel electrode 126α9 included in the third pixel column C3 is charged to have the negative potential related to the image signal S2, the first pixel electrode 126α10 included in the fourth pixel column C4 is charged to have the negative potential related to the image signal S2, the first pixel electrode 126α7 included in the fifth pixel column C5 is charged to have the positive potential related to the image signal S1, the first pixel electrode 126α8 included in the sixth pixel column C6 is charged to have the positive potential related to the image signal S1, and the first pixel electrode 126α11 included in the seventh pixel column C7 is charged to have the negative potential related to the image signal S2. Thus, in the second pixel row R2, every two of the first pixel electrodes 126α that are adjacent to each other in the X-axis direction have the potential of a same polarity. Specifically, in the second pixel row R2, the (4n−3)th pixel column and the (4n−2)th pixel column from the left end in FIG. 21 have positive potential and the (4n−1)th pixel column and the 4nth pixel column have negative potential (n: natural number). Namely, in the first pixel row R1 and the second pixel row R2, the first pixel electrodes 126α included in the same pixel column have opposite polarities.

One frame display period after the output of the signals illustrated in FIG. 20, the signals illustrated in FIG. 22 are outputted. Among the signals illustrated in FIG. 22, the scanning signal G1 and the control signals SWA to SWD are same as those illustrated in FIG. 20; however, the image signals S0 to S2 have opposite polarities from those illustrated in FIG. 20. Specifically, the negative image signal S1 is supplied to the first source line 128α and the second source line 128β. The positive image signal S2 is supplied to the third source line 128γ and the fourth source line 128δ. The positive image signal S0 is supplied to the fifth source line 128ζ.

With the signals illustrated in FIG. 22 being outputted, as illustrated in FIG. 23, in the first pixel row R1, the first pixel electrode 126α12 included in the second pixel column C2 is charged to have the positive potential related to the image signal S0, the first pixel electrode 126α5 included in the third pixel column C3 is charged to have the negative potential related to the image signal S1, the first pixel electrode 126α6 included in the fourth pixel column C4 is charged to have the negative potential related to the image signal S1, the first pixel electrode 126α9 included in the fifth pixel column C5 is charged to have the positive potential related to the image signal S2, the first pixel electrode 126α10 included in the sixth pixel column C6 is charged to have the positive potential related to the image signal S2, the first pixel electrode 126α7 included in the seventh pixel column C7 is charged to have the negative potential related to the image signal S1, and the first pixel electrode 126α8 included in the eighth pixel column C8 is charged to have the negative potential related to the image signal S1. Thus, the polarities of the pixel electrodes 126α5 to 126α12 are inverted from those illustrated in FIG. 21. Specifically, in the first pixel row R1, the (4n−3)th pixel column and the (4n−2)th pixel column from the left end in FIG. 23 have positive potential and the (4n−1)th pixel column and the 4nth pixel column have negative potential (n: natural number).

On the other hand, in the second pixel row R2, the first pixel electrode 126α5 included in the first pixel column C1 is charged to have the negative potential related to the image signal S1, the first pixel electrode 126α6 included in the second pixel column C2 is charged to have the negative potential related to the image signal S1, the first pixel electrode 126α9 included in the third pixel column C3 is charged to have the positive potential related to the image signal S2, the first pixel electrode 126α10 included in the fourth pixel column C4 is charged to have the positive potential related to the image signal S2, the first pixel electrode 126α7 included in the fifth pixel column C5 is charged to have the negative potential related to the image signal S1, the first pixel electrode 126α8 included in the sixth pixel column C6 is charged to have the negative potential related to the image signal S1, and the first pixel electrode 126α11 included in the seventh pixel column C7 is charged to have the positive potential related to the image signal S2. Thus, the polarities of the pixel electrodes 126α5 to 126α12 are inverted from those illustrated in FIG. 21. Specifically, in the second pixel row R2, the (4n−3)th pixel column and the (4n−2)th pixel column from the left end in FIG. 23 have negative potential and the (4n−1)th pixel column and the 4nth pixel column have positive potential (n: natural number). Namely, in the first pixel row R1 and the second pixel row R2, the first pixel electrodes 126α included in the same pixel column have opposite polarities. Therefore, in this embodiment, with two first pixel electrodes 126α that are adjacent to each other in the X-axis direction and have a same polarity being defined as one group, the groups that are adjacent to the X-axis direction and the Y-axis direction have opposite polarities and are arranged in a zig-zag form.

As previously described, in this embodiment, the pixel electrodes 126 include the first pixel electrodes 126α. The first pixel electrodes 126α include the first pixel electrode 126α5, the first pixel electrode 126α6, the first pixel electrode 126α9, the first pixel electrode 126α10, the first pixel electrode 126α7, and the first pixel electrode 126α8. The first body portion 126Aα of the first pixel electrode 126α5 is disposed between the first source line 128α and the second control line 129 in the first direction and the first connection line portion 126Bα of the first pixel electrode 126α5 is connected to the second drain electrode 125C of the first control TFT 125α and crosses the first source line 128α. The first body portion 126Aα of the first pixel electrode 126α6 is disposed between the second control line 129β and the third source line 128γ in the first direction and the first connection line portion 126Bα of the first pixel electrode 126α6 is connected to the second drain electrode 125C of the second control TFT 125β and crosses the second control line 129β. The first body portion 126Aα of the first pixel electrode 126α9 is disposed between the third source line 128γ and the third control line 129γ in the first direction and the first connection line portion 126Bα of the first pixel electrode 126α9 is connected to the second drain electrode 125C of the fifth control TFT 125ζ and crosses the third source line 128γ. The first body portion 126Aα of the first pixel electrode 126α10 is disposed between the third control line 129γ and the second source line 128β in the first direction and the first connection line portion 126Bα of the first pixel electrode 126α10 is connected to the second drain electrode 125C of the sixth control TFT 125η and crosses the third control line 129γ. The first body portion 126Aα of the first pixel electrode 126α7 is disposed between the second source line 128β and the fourth control line 129δ in the first direction and the first connection line portion 126Bα of the first pixel electrode 126α7 is connected to the second drain electrode 125C of the third control TFT 125γ and crosses the second source line 128β. The first body portion 126Aα of the first pixel electrode 126α8 is disposed on an opposite side from the second source line 128β with respect to the fourth control line 129δ in the first direction and the first connection line portion 126Bα of the first pixel electrode 126α8 is connected to the second drain electrode 125C of the fourth control TFT 125δ and crosses the fourth control line 129δ. A signal supplied to the first source line 128α is supplied to the first pixel electrode 126α5 that is connected to the first control TFT 125α at the timing when high potential is supplied to the first control line 129α and is supplied to the first pixel electrode 126α6 that is connected to the second control TFT 125β at the timing when high potential is supplied to the second control line 129β. A signal supplied to the second source line 128β is supplied to the first pixel electrode 126α7 that is connected to the third control TFT 125γ at the timing when high potential is supplied to the third control line 129γ and is supplied to the first pixel electrode 126α8 that is connected to the fourth control TFT 125δ at the timing when high potential is supplied to the fourth control line 129δ. A signal supplied to the third source line 128γ is supplied to the first pixel electrode 126α9 that is connected to the fifth control TFT 125ζ at the timing when high potential is supplied to the second control line 129β and is supplied to the first pixel electrode 126α10 that is connected to the sixth control TFT 125η at the timing when high potential is supplied to the third control line 129γ.

This embodiment further includes the driver 12 that is connected to the source lines 128 and supplies signals to the source lines 128. The signals supplied to the first source line 128α and the second source line 128β from the driver 12 and the signals supplied to the third source line 128γ from the driver 12 have opposite polarities. With the first pixel electrodes 126α being connected to the first control TFT 125α, the second control TFT 125β, the third control TFT 125γ, the fourth control TFT 125δ, the fifth control TFT 125ζ, and the sixth control TFT 125η, respectively, and the signals supplied to the first source line 128α and second source line 128β and the signals supplied to the third source line 128γ having opposite polarities, two pixel electrodes 126 that are adjacent to each other in the first direction are charged to have the potential having a same polarity. Specifically, the first pixel electrode 126α that is connected to the first control TFT 125α and the first pixel electrode 126α that is connected to the second control TFT 125β have a same polarity. The first pixel electrode 126α that is connected to the second control TFT 125β and the first pixel electrode 126α that is connected to the fifth control TFT 125ζ have opposite polarities. The first pixel electrode 126α that is connected to the fifth control TFT 1250 and the first pixel electrode 126α that is connected to the sixth control TFT 125η have a same polarity. The first pixel electrode 126α that is connected to the sixth control TFT 125η and the first pixel electrode 126α that is connected to the third control TFT 125γ have opposite polarities. The first pixel electrode 126α that is connected to the third control TFT 125γ and the first pixel electrode 126α that is connected to the fourth control TFT 125δ have a same polarity.

### Third Embodiment

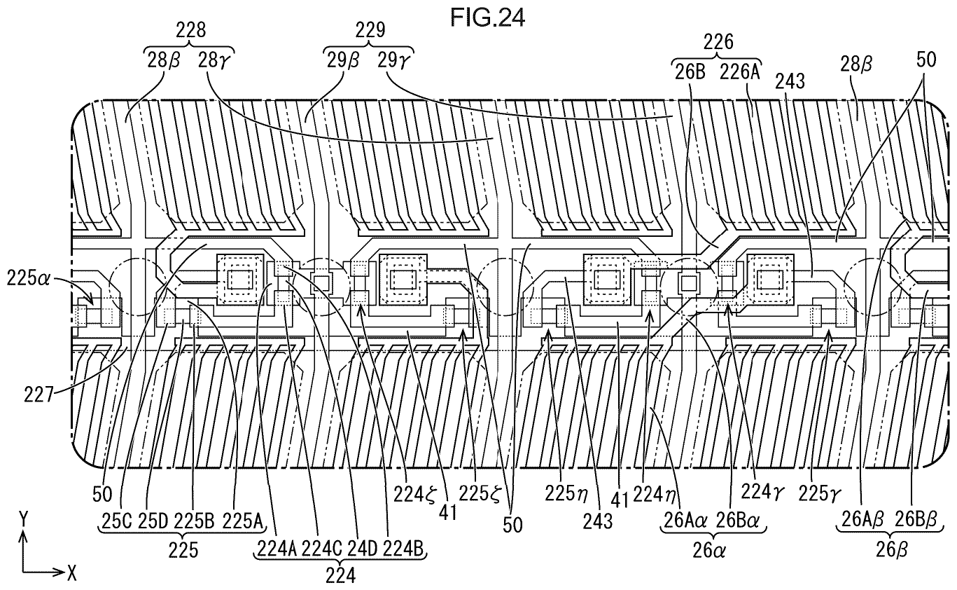

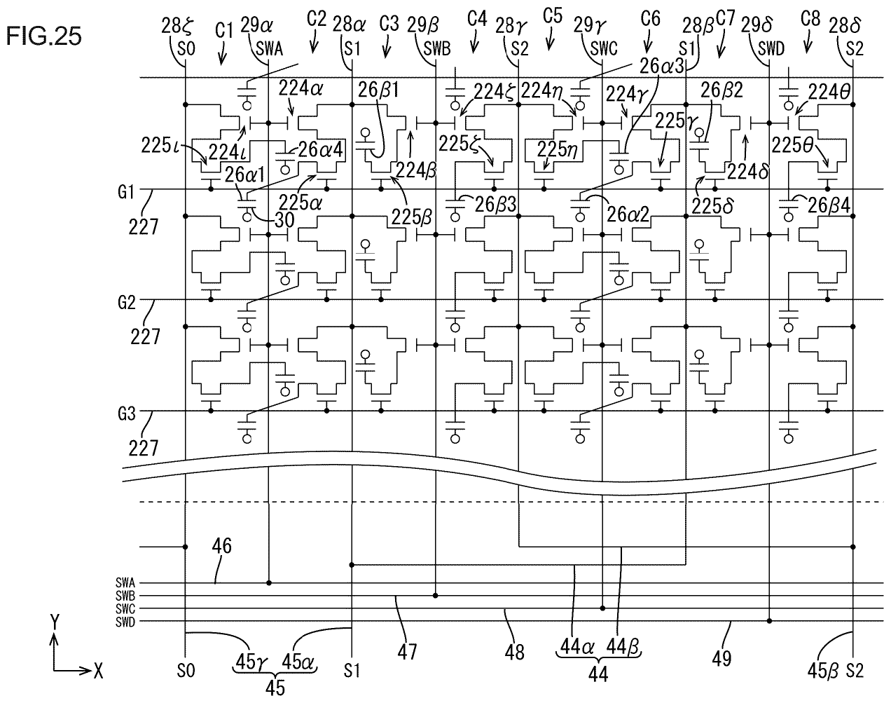

A third embodiment will be described with reference to FIGS. 24 and 25. The third embodiment includes first TFTs 224 and second TFTs 225 having configurations different from those of the first embodiment. Configuration, operations, and effects similar to those of the first embodiment may not be described.

As illustrated in FIGS. 24 and 25, the first TFTs 224 are connected to control lines 229. The second TFTs 225 are connected to the gate lines 227. Specifically, a first gate electrode 224A of the first TFT 224 is connected to the control line 229. Therefore, the first TFT 224 is configured to be driven based on a control signal supplied to the control line 229 from the control board 14. A second gate electrode 225A of the second TFT 225 is connected to the gate line 227. Therefore, the second TFT 225 is configured to be driven based on a scanning signal supplied to the gate line 227 from the gate driver circuit 15.

As illustrated in FIG. 24, the first TFT 224 is closer to the control line 229 than the source line 228 in the X-axis direction. Accordingly, a first source electrode 224B of the first TFT 224 is connected to the source line 228, which is a target to be connected, via a source line section 50. The source line section 50 is between a body portion 226A and a drain line section 243 in the Y-axis direction. The source line section 50 extends along the X-axis direction and includes a first end portion connected to the first source electrode 224B and a second end portion connected to the source line 228. The source line section 50 is a portion of the second metal film and is directly continuous to the first source electrode 224B and the source line 228, which are targets to be connected. The second TFT 225 is closer to the source line 228 than the control line 229 in the X-axis direction.

With such a configuration, as illustrated in FIG. 25, while high potential of the scanning signal G1 is supplied to the gate line 227, high potential of the control signals SWA to SWD is supplied to the control lines 229α to 229δ in a predefined order and the image signals S0 to S2 are supplied to the source lines 228α to 228ζ in synchronization with the timing at which the control signals SWA to SWD rise up to have high potential. Some of the first TFTs 224 to which the control signals SWA to SWD having high potential are supplied are selectively driven. The image signal S0 to S2 supplied to the source line 228α to 228ζ is supplied from the first drain electrode 224C of the driven first TFT 224 to the second source electrode 225B of the second TFT 225. The second TFTs 225 that are connected to the gate line 227 are collectively driven. Therefore, the pixel electrode 226 that is connected to one of the second TFTs 225 to which the image signal S0 to S2 is supplied from the driven first TFT 224 is selectively charged to have the potential related to the image signal S0 to S2.

As previously described, according to this embodiment, the first gate electrode 224A is connected to the control line 229 and the second gate electrode 225A is connected to the gate line 227. With a signal being supplied to the gate line 227, the second TFT 225 including the second gate electrode 225A that is connected to the gate line 227 is driven. With a signal being supplied to the control line 229, the first TFT 224 including the first gate electrode 224A that is connected to the control line 229 is driven.

### Other Embodiments

The technology described herein is not limited to the embodiments described above and illustrated by the drawings. For example, the following embodiments will be included in the technical scope of the present technology.

(1) A specific planar arrangement of the body portions 26A, 226A of the pixel electrodes 26, 126, 226 may be altered as appropriate from that illustrated in the drawings.

(2) A specific planar form (routing path) of the connection line portions 26B, 126B of the pixel electrodes 26, 126, 226 may be altered as appropriate from that illustrated in the drawings. For instance, in the configuration of the first embodiment and the third embodiment, the connection line portions 26B of the pixel electrodes 26, 226 included in one pixel row may be connected to the second TFTs 25, 225 included in the same pixel row. In the configuration of the second embodiment, some of the connection line portions 126β of the pixel electrodes 126 included in one pixel row may be connected to the second TFTs 125 included in another pixel row.

(3) A specific planar shape of the body portion 26A, 226A of the pixel electrode 26, 126, 226 may be altered as appropriate from that illustrated in the drawings. For instance, the body portion 26A, 226A may have a vertically long rectangular shape without having a bent portion or may have a laterally long rectangular shape. The body portion 26A, 226A may have a vertically long rectangular shape or a laterally long rectangular shape having bent portions.

(4) A specific planar arrangement of the first TFTs 24, 124, 224 may be altered as appropriate from that illustrated in the drawings. For instance, in the configuration of the first embodiment and the second embodiment, the first TFT 24, 124 may be closer to the control line 29, 129 than the source line 28, 128 in the X-axis direction. In the configuration of the first embodiment and the second embodiment, the first TFT 24, 124 may be in a middle between the source line 28, 128 and the control line 29, 129 in the X-axis direction. In the configuration of the third embodiment, the first TFT 224 may be closer to the source line 228 than the control line 229 in the X-axis direction. In the configuration of the third embodiment, the first TFT 224 may be in a middle between the control line 229 and the source line 228 in the X-axis direction.

(5) A specific planar arrangement of the second TFTs 25, 125, 225 may be altered as appropriate from that illustrated in the drawings. For instance, in the configuration of the first embodiment and the second embodiment, the second TFT 25, 125 may be closer to the source line 28, 128 than the control line 29, 129 in the X-axis direction. In the configuration of the first embodiment and the second embodiment, the second TFT 25, 125 may be in a middle between the source line 28, 128 and the control line 29, 129 in the X-axis direction. In the configuration of the third embodiment, the second TFT 225 may be closer to the control line 229 than the source line 228 in the X-axis direction. In the configuration of the third embodiment, the second TFT 225 may be in a middle between the control line 229 and the source line 228 in the X-axis direction.

(6) The number of the control lines 29, 129, 229 may not be necessarily even but may be odd.

(7) The ratio of the number of the source lines 28, 128, 228 and the number of the control lines 29, 129, 229 may be altered as appropriate from that illustrated in the drawings.

(8) The first extending line 45α may be connected to the second source line 28β, 128β. The second extending line 45B may be connected to the third source line 28γ, 128γ.

(9) The extending line 45 may be connected to the short circuit line 44.

(10) The source lines 28, 128, 228 and the control lines 29, 129, 229 may extend straight along the Y-axis direction. In such a configuration, the body portions 26A, 226A of the pixel electrodes 26, 126, 226 and the color filters 31 may extend straight along the Y-axis direction so as to be parallel to the side edges of the source lines 28, 128, 228 and the control lines 29, 129, 229.

(11) The short circuit line 44 may connect three or more source lines 28, 128, 228 to cause short-circuit therebetween.

(12) Three or less kinds of control signals or five or more kinds of control signals may be supplied to the control lines 29, 129, 229 at different timings from the control board 14.

(13) The short circuit line 44 may not be included. In such a configuration, the extending lines 45 may be connected to the source lines 28, 128, 228, respectively, and image signals from the driver 12 may be supplied to each of the source lines 28, 128, 228 via each extending line 45.

(14) Control signals may be supplied from the driver 12 to the control line 29, 129, 229. In such a configuration, the driver 12 is configured as the second signal supply section and the first signal supply section.

(15) A planar arrangement and the number of the spacers 40 may be altered as appropriate from those illustrated in the drawings.

(16) The driver 12 may be mounted on the flexible substrate 13 through the chip-on-film (COF) technology. A gate driver may be mounted on the array substrate 21 instead of the gate drive circuit 15.

(17) Material of the semiconductor film of the semiconductor section 24D, 25D may be amorphous silicon material and polycrystalline silicon material.

(18) The TFT 24, 25, 124, 125, 224, 225 may be a bottom gate TFT, a top gate TFT, or a double gate TFT.

(19) The pixel electrodes 26, 126, 226 may be portions of the first transparent electrode film and the common electrode 30 may be a portion of the second transparent electrode film. In such a configuration, the common electrode 30 preferably includes slits for controlling orientation.

(20) The planar shape of the liquid crystal panel 11 may be vertically elongated rectangle, a square, a circle, a semicircle, a vertically elongated oval, an oval, or a trapezoid.

(21) The liquid crystal panel 11 may be a reflective liquid crystal panel or a semitransmissive liquid crystal panel other than the transmissive liquid crystal panel. With the liquid crystal panel 11 being a reflective liquid crystal panel, the backlight unit is not necessary.

(22) The display mode of the liquid crystal panel 11 may be the MVA (multi-domain vertical alignment) mode, the IPS (in-plane switching) mode, and the TN (twisted nematic) mode.

(23) Display panels other than the liquid crystal panel 11 such as organic electro luminescence (EL) display panels and electric paper display panels. In a microcapsule-based electrophoretic electronic paper display, the common electrode 30 is included in the opposed substrate 20 and the pixel electrodes 26 included in the array substrate 21 may be made of metal material having high reflectance such as platinum, silver, aluminum, and nickel in addition to the transparent electrode material. The liquid crystal layer 22 is not included and a microcapsule layer may be between the pixel electrodes 26 and the common electrode 30 as the substance whose optical characteristics vary according to application of electric field. The first alignment film 34 and the second alignment film 39 are not included. The microcapsule layer includes microcapsules made of transparent resin and each of the microcapsules has a diameter of several tens μm to several hundreds μm. The microcapsules include positive-charged white particles and negative-charged black particles that are dispersed in transparent disperse medium. By applying positive or negative voltage to the microcapsule layer, the white particles and the black particles in the microcapsules move with electrophoresis and an image is displayed.

1. A display device comprising:
a scan line extending along a first direction;
a signal line extending along a second direction that crosses the first direction, the signal line crossing the scan line;
a control line extending along the second direction and disposed to be spaced from the signal line and crossing the scan signal;
pixel electrodes arranged in a matrix in the first direction and the second direction;
a first switching component; and
a second switching component, wherein
the first switching component includes
a first electrode connected to one of the scan line and the control line,
a second electrode connected to the signal line,
a third electrode, and
a first semiconductor section connected to the second electrode and the third electrode and overlapping the first electrode,
the second switching component includes
a fourth electrode connected to another one of the scan line and the control line,
a fifth electrode connected to the third electrode,
a sixth electrode connected to one of the pixel electrodes, and
a second semiconductor section connected to the fifth electrode and the sixth electrode and overlapping the fourth electrode,
the pixel electrodes include a first pixel electrode,
the first pixel electrode includes a first body portion and a first connection line portion that is connected to the first body portion and the sixth electrode, and
the first connection line portion crosses the control line or the signal line.

2. The display device according to claim 1, wherein the control line or the signal line is disposed between the first body portion and the second switching component that is connected to the first connection line portion.

3. The display device according to claim 1, wherein
the first electrode is connected to the scan line, and
the fourth electrode is connected to the control line.

4. The display device according to claim 3, wherein the second switching component is disposed closer to the control line than the signal line.

5. The display device according to claim 3, wherein the first switching component is disposed closer to the signal line than the control line.

6. The display device according to claim 3, wherein
the control line includes control lines that are arranged at intervals in the first direction,
the control lines include a first control line and a second control line,
the signal line includes signal lines that are arranged at intervals in the first direction,
the signal lines include a first signal line,
the second switching component includes second switching components that are arranged at intervals in the first direction,
one of the second switching components that includes the fourth electrode connected to the first control line is defined as a first control switching component,
another one of the second switching components that includes the fourth electrode connected to the second control line is defined as a second control switching component, and
the first switching component includes first switching components that are arranged at intervals in the first direction,
one of the first switching components that includes the second electrode connected to the first signal line and the third electrode connected to the fifth electrode of the first control switching component is defined as a first signal switching component, and
another one of the first switching components that includes the second electrode connected to the first signal line and the third electrode connected to the fifth electrode of the second control switching component is defined as a second signal switching component.

7. The display device according to claim 6, further comprising a first signal supply section connected to the control lines and configured to supply signals to the control lines and configured to supply high-level potential to the first control line and the second control line at different timings.

8. The display device according to claim 6, wherein
the control lines include a third control line and a fourth control line,
the signal lines include a second signal line,
other one of the second switching components that includes the fourth electrode connected to the third control line is defined as a third control switching component,
other one of the second switching components that includes the fourth electrode connected to the fourth control line is defined as a fourth control switching component,
other one of the first switching components that includes the second electrode connected to the second signal line and the third electrode connected to the fifth electrode of the third control switching component is defined as a third signal switching component, and
other one of the first switching components that includes the second electrode connected to the second signal line and the third electrode connected to the fifth electrode of the fourth control switching component is defined as a fourth signal switching component.

9. The display device according to claim 8, further comprising:
a first short circuit line extending along the first direction and connected to the first signal line and the second signal line to cause a short circuit between the first signal line and the second signal line;
a first extending line connected to one of the first signal line, the second signal line, and the first short circuit line; and
a second supply section connected to the first extending line and configured to supply signals to the first extending line.

10. The display device according to claim 9, further comprising a first signal supply section connected to the control lines and configured to supply signals to the control lines, wherein
the first signal supply section is configured to supply high-level potential to the first control line, the second control line, the third control line, and the fourth control line at different timings,
the second signal supply section is configured to
supply a signal to the first signal switching component in synchronization with a timing when high-level potential is supplied to the first control line,
supply a signal to the second signal switching component in synchronization with a timing when high-level potential is supplied to the second control line,
supply a signal to the third signal switching component in synchronization with a timing when high-level potential is supplied to the third control line, and
supply a signal to the fourth signal switching component in synchronization with a timing when high-level potential is supplied to the fourth control line.

11. The display device according to claim 8 wherein,
the first signal line is between the first control line and the second control line in the first direction,
the second signal line is between the third control line and the fourth control line in the first direction,
the signal lines include a third signal line that is between the second control line and the third control line in the first direction,
other one of the first switching components that includes the second electrode connected to the third signal line is defined as a fifth signal switching component,
other one of the first switching components that includes the second electrode connected to the third signal line and sandwiches the third signal line with the fifth signal switching component is defined as a sixth signal switching component,
other one of the second switching components that includes the fifth electrode connected to the third electrode of the fifth signal switching component is defined as a fifth control switching component,
other one of the second switching components that includes the fifth electrode connected to the third electrode of the sixth signal switching component is defined as a sixth control switching component,
the fourth electrode of the fifth control switching component is connected to the second control line, and
the fourth electrode of the sixth control switching component is connected to the third control line.

12. The display device according to claim 11, wherein
the signal lines include a fourth signal line that sandwiches the fourth control line with the second signal line,
other one of the first switching components that includes the second electrode connected to the fourth signal line is defined as a seventh signal switching component,
other one of the second switching components that includes the fifth electrode connected to the third electrode of the seventh signal switching component is defined as a seventh control switching component, and
the fourth electrode of the seventh control switching component is connected to the fourth control line.

13. The display device according to claim 11, wherein
the first pixel electrode includes first pixel electrodes and the pixel electrodes further include second pixel electrodes,
each of the second pixel electrodes includes a second body portion and a second connection line portion that is connected to the second body portion and the sixth electrode and does not cross the control line and the signal line,
one of the first pixel electrodes includes the first body portion that is on an opposite side from the first signal line with respect to the first control line in the first direction and the first connection line portion that is connected to the sixth electrode of the first control switching component and crosses the first control line,
other one of the first pixel electrodes includes the first body portion that is between the third signal line and the third control line in the first direction and the first connection line portion that is connected to the sixth electrode of the third control switching component and crosses the third control line,
other one of the first pixel electrodes includes the first body portion that is between the third control line and the second signal line in the first direction and the first connection line portion that is connected to the sixth electrode of the sixth control switching component and crosses the third control line,
one of the second pixel electrodes includes the second body portion that is between the first signal line and the second control line in the first direction and the second connection line portion that is connected to the sixth electrode of the second control switching component,
other one of the second pixel electrodes includes the second body portion that is between the second signal line and the fourth control line in the first direction and the second connection line portion that is connected to the sixth electrode of the fourth control switching component, and
other one of the second pixel electrodes includes the second body portion that is between the second control line and the third signal line in the first direction and the second connection line portion that is connected to the sixth electrode of the fifth control switching component.

14. The display device according to claim 13, wherein
the first body portion and the second body portion have a same area, and
the first connection line portion and the second connection line portion have a same area.

15. The display device according to claim 13, wherein
the first connection line portion has a first length extending from the first body portion to the sixth electrode and the second connection line portion has a second length extending from the second body portion to the sixth electrode, and
the first length is same as the second length.

16. The display device according to claim 11, wherein
the first pixel electrode includes first pixel electrodes,
one of the first pixel electrodes includes the first body portion that is between the first signal line and the second control line in the first direction and the first connection line portion that is connected to the sixth electrode of the first control switching component and crosses the first signal line,
other one of the first pixel electrodes includes the first body portion that is between the second control line and the third signal line in the first direction and the first connection line portion that is connected to the sixth electrode of the second control switching component and crosses the second control line,
other one of the first pixel electrodes includes the first body portion that is between the third signal line and the third control line in the first direction and the first connection line portion that is connected to the sixth electrode of the fifth control switching component and crosses the third signal line,
other one of the first pixel electrodes includes the first body portion that is between the third control line and the second signal line in the first direction and the first connection line portion that is connected to the sixth electrode of the sixth control switching component and crosses the third control line,
other one of the first pixel electrodes includes the first body portion that is between the second signal line and the fourth control line in the first direction and the first connection line portion that is connected to the sixth electrode of the third control switching component and crosses the second signal line, and
other one of the first pixel electrodes includes the first body portion that is on an opposite side from the second signal line with respect to the fourth control line in the first direction and the first connection line portion that is connected to the sixth electrode of the fourth control switching component and crosses the fourth control line.

17. The display device according to claim 13, further comprising a second signal supply section connected to the signal lines and configured to supply signals to the signal lines, wherein
signals supplied by the second signal supply section to the first signal line and the second signal line and signals supplied by the second signal supply section to the third signal line have opposite polarities.

18. The display device according to claim 17, further comprising a first signal supply section connected to the control lines and configured to supply signals to the control lines, wherein
the second signal supply section is configured to supply signals having a same polarity to the first signal line, the second signal line, and the third signal line in synchronization with supply of high-level potential to the first control line, the second control line, the third control line, and the fourth control line from the first signal supply section.

19. The display device according to claim 1, wherein
the first electrode is connected to the control line, and
the fourth electrode is connected to the scan line.
